(19) United States
(12) Patent Application Publication
(10) Pub. No.: US 2022/0010072 A1
(43) Pub. Date: Jan. 13, 2022

(54) FILM FORMING MATERIAL FOR LITHOGRAPHY, COMPOSITION FOR FILM FORMATION FOR LITHOGRAPHY, UNDERLAYER FILM FOR LITHOGRAPHY, AND METHOD FOR FORMING PATTERN

(71) Applicant: Mitsubishi Gas Chemical Company, Inc., Tokyo (JP)

(72) Inventors: Kouichi YAMADA, Kurashiki-shi, Okayama (JP); Junya HORIUCHI, Hiratsuka-shi, Kanagawa (JP); Takashi MAKINOSHIMA, Hiratsuka-shi, Kanagawa (JP); Masatoshi ECHIGO, Chiyoda-ku, Tokyo (JP)

(21) Appl. No.: 17/295,830

(22) PCT Filed: Nov. 21, 2019
(86) PCT No.: PCT/JP2019/045546

§ 371 Date: May 20, 2021

(30) Foreign Application Priority Data
Nov. 21, 2018 (JP) 2018-218125

(51) Int. Cl. C08G 73/12; G03F 7/26; G03F 7/20; G03F 7/039

(52) U.S. Cl. CPC C08G 73/12; G03F 7/0392; G03F 7/20; G03F 7/26

(57) ABSTRACT

A film forming material for lithography comprising a maleimide resin represented by the following formula (1A)

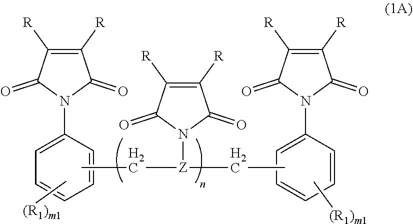

### TECHNICAL FIELD

The present invention relates to a film forming material for lithography, a composition for film formation for lithography containing the material, an underlayer film for lithography formed by using the composition, and a method for forming a pattern (for example, a method for forming a resist pattern or a circuit pattern) by using the composition.

### BACKGROUND ART

In the production of semiconductor devices, fine processing is practiced by lithography using photoresist materials. In recent years, further miniaturization based on pattern rules has been demanded along with increase in the integration and speed of LSI. And now, lithography using light exposure, which is currently used as a general purpose technique, is approaching the limit of essential resolution derived from the wavelength of a light source.

The light source for lithography used upon forming resist patterns has been shifted to ArF excimer laser (193 nm) having a shorter wavelength from KrF excimer laser (248 nm). However, when the miniaturization of resist patterns proceeds, the problem of resolution or the problem of collapse of resist patterns after development arises. Therefore, resists have been desired to have a thinner film. Nevertheless, if resists merely have a thinner film, it is difficult to obtain the film thicknesses of resist patterns sufficient for substrate processing. Therefore, there has been a need for a process of preparing a resist underlayer film between a resist and a semiconductor substrate to be processed, and imparting functions as a mask for substrate processing to this resist underlayer film in addition to a resist pattern.

Various resist underlayer films for such a process are currently known. For example, as a material for realizing resist underlayer films for lithography having the selectivity of a dry etching rate close to that of resists, unlike conventional resist underlayer films having a fast etching rate, an underlayer film forming material for a multilayer resist process containing a resin component having at least a substituent that generates a sulfonic acid residue by eliminating a terminal group under application of predetermined energy, and a solvent has been suggested (see Patent Literature 1). Moreover, as a material for realizing resist underlayer films for lithography having the selectivity of a dry etching rate smaller than that of resists, a resist underlayer film material comprising a polymer having a specific repeat unit has been suggested (see Patent Literature 2). Furthermore, as a material for realizing resist underlayer films for lithography having the selectivity of a dry etching rate smaller than that of semiconductor substrates, a resist underlayer film material comprising a polymer prepared by copolymerizing a repeat unit of an acenaphthylene and a repeat unit having a substituted or unsubstituted hydroxy group has been suggested (see Patent Literature 3).

Meanwhile, as materials having high etching resistance for this kind of resist underlayer film, amorphous carbon underlayer films formed by CVD using methane gas, ethane gas, acetylene gas, or the like as a raw material are well known.

In addition, the present inventors have suggested an underlayer film forming composition for lithography containing a naphthalene formaldehyde polymer comprising a particular constituent unit and an organic solvent as a material that is not only excellent in optical properties and etching resistance, but also is soluble in a solvent and applicable to a wet process (see Patent Literatures 4 and 5).

As for methods for forming an intermediate layer used in the formation of a resist underlayer film in a multilayer process, for example, a method for forming a silicon nitride film (see Patent Literature 6) and a CVD formation method for a silicon nitride film (see Patent Literature 7) are known. Also, as for formation of a coating type intermediate layer, materials comprising a silsesquioxane-based silicon compound are known (see Patent Literatures 8 and 9). Recently, with the progress of miniaturization, the formation of more compact intermediate layers is required, aiming at improvement in etching selectivity, and a CVD formation method of a silicon nitride film, which requires heat treatment at a high temperature exceeding 400° C., has been employed.

### CITATION LIST

### Patent Literature

Patent Literature 1: Japanese Patent Application Laid-Open No. 2004-177668
Patent Literature 2: Japanese Patent Application Laid-Open No. 2004-271838
Patent Literature 3: Japanese Patent Application Laid-Open No. 2005-250434
Patent Literature 4: International Publication No. WO 2009/072465
Patent Literature 5: International Publication No. WO 2011/034062
Patent Literature 6: Japanese Patent Application Laid-Open No. 2002-334869
Patent Literature 7: International Publication No. WO 2004/066377
Patent Literature 8: Japanese Patent Application Laid-Open No. 2007-226170
Patent Literature 9: Japanese Patent Application Laid-Open No. 2007-226204

### SUMMARY OF INVENTION

### Technical Problem

As mentioned above, a large number of film forming materials for lithography have heretofore been suggested. However, none of these materials not only have high solvent solubility that permits application of a wet process such as spin coating or screen printing but also achieve all of film heat resistance during baking at a high temperature exceeding 400° C., embedding properties to a substrate having difference in level, and film flatness at high dimensions. Thus, the development of novel materials is required.

The present invention has been made in light of the problems described above, and an object of the present invention is to provide a film forming material for lithography that is applicable to a wet process, and is useful for forming a photoresist underlayer film excellent in film heat resistance during baking at a high temperature exceeding 400° C., embedding properties to a substrate having difference in level, and film flatness; a composition for film formation for lithography comprising the material; as well as an underlayer film for lithography and a method for forming a pattern by using the composition.

### Solution to Problem

The present inventors have, as a result of devoted examinations to solve the above problems, found out that use of a compound having a specific structure can solve the above problems, and reached the present invention. More specifically, the present invention is as follows.

[1]

A film forming material for lithography comprising a maleimide resin represented by the following formula (1A)

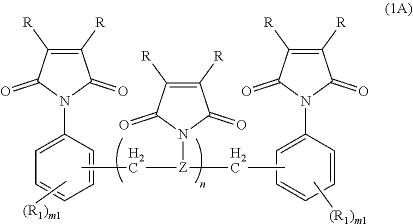

(In formula (1A),

each R is independently any one group selected from the group consisting of a hydrogen atom and an alkyl group having 1 to 4 carbon atoms;

each Z is independently a trivalent or tetravalent hydrocarbon group having 1 to 100 carbon atoms and optionally containing a heteroatom;

each R₁ is independently a group having 0 to 10 carbon atoms and optionally containing a heteroatom;

each m1 is independently an integer of 0 to 4; and

n is an integer of 1 or more.) [2]

The film forming material for lithography according to the above [1], wherein n is an integer of 2 or more.

[3]

The film forming material for lithography according to the above [1], wherein the maleimide resin of formula (1A) is represented by the following formula (2A):

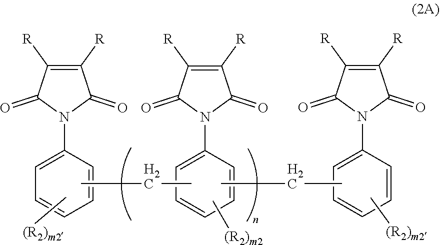

(In formula (2A), R is as defined in formula (1A);

each R₂ is independently a group having 0 to 10 carbon atoms and optionally containing a heteroatom;

each m2 is independently an integer of 0 to 3;

each m2′ is independently an integer of 0 to 4; and

n is an integer of 1 or more),

or by the following formula (3A):

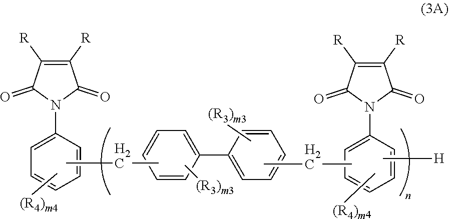

(In formula (3A), R is as defined in formula (1A);

R₃ and R₄ are each independently a group having 0 to 10 carbon atoms and optionally containing a heteroatom;

each m3 is independently an integer of 0 to 4;

each m4 is independently an integer of 0 to 4; and

n is an integer of 2 or more.).

[3-1]

The film forming material for lithography according to the above [2], wherein the maleimide resin of formula (2A) or formula (3A) is represented by the following formula (2B):

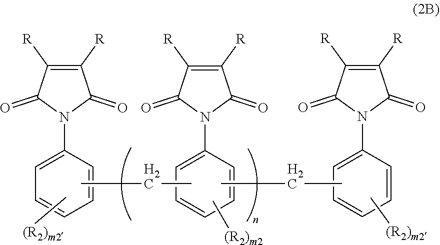

(In formula (2B), R, R₂, m2, and m2′ are as defined in formula (2A); and

n is an integer of 2 or more.),

or by the following formula (3B):

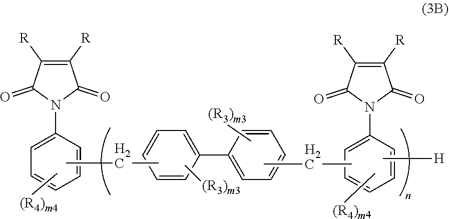

(In formula (3B), R, R₃, R₄, m3, and m4 are as defined in formula (3A); and

n is an integer of 3 or more.).

[4]

The film forming material for lithography according to any of the above [1] to [3], wherein the heteroatom is selected from the group consisting of oxygen, fluorine, and silicon.

[5]

The film forming material for lithography according to any of the above [1] to [4], further comprising a crosslinking agent.

[6]

The film forming material for lithography according to the above [5], wherein the crosslinking agent is at least one selected from the group consisting of a phenol compound, an epoxy compound, a cyanate compound, an amino compound, a benzoxazine compound, a melamine compound, a guanamine compound, a glycoluril compound, a urea compound, an isocyanate compound, and an azide compound.

[7]

The film forming material for lithography according to the above [5] or [6], wherein the crosslinking agent has at least one allyl group.

[8]

The film forming material for lithography according to any of the above [1] to [7], further comprising a crosslinking promoting agent.

[9]

The film forming material for lithography according to the above [8], wherein the crosslinking promoting agent is at least one selected from the group consisting of an amine, an imidazole, an organic phosphine, and a Lewis acid.

[10]

The film forming material for lithography according to the above [8] or [9], wherein a content ratio of the crosslinking promoting agent is 0.1 to 5 parts by mass based on 100 parts by mass of a total mass of the maleimide resin.

[11]

The film forming material for lithography according to any of the above [1] to [10], further comprising a radical polymerization initiator.

[12]

The film forming material for lithography according to the above [11], wherein the radical polymerization initiator is at least one selected from the group consisting of a ketone-based photopolymerization initiator, an organic peroxide-based polymerization initiator, and an azo-based polymerization initiator.

[13]

The film forming material for lithography according to the above [11] or [12], wherein a content ratio of the radical polymerization initiator is 0.05 to 25 parts by mass based on 100 parts by mass of a total mass of the maleimide resin.

[14]

A composition for film formation for lithography comprising the film forming material for lithography according to any of the above [1] to [13] and a solvent.

[15]

The composition for film formation for lithography according to the above [14], further comprising a base generating agent.

[16]

The composition for film formation for lithography according to the above [14] or [15], wherein the film for lithography is an underlayer film for lithography.

[17]

An underlayer film for lithography formed by using the composition for film formation for lithography according to the above [16].

[18]

A method for forming a resist pattern, comprising the steps of:

forming an underlayer film on a substrate by using the composition for film formation for lithography according to the above [16];

forming at least one photoresist layer on the underlayer film; and

irradiating a predetermined region of the photoresist layer with radiation for development.

[19]

A method for forming a circuit pattern, comprising the steps of:

forming an underlayer film on a substrate by using the composition for film formation for lithography according to the above [16];

forming an intermediate layer film on the underlayer film by using a resist intermediate layer film material containing a silicon atom;

forming at least one photoresist layer on the intermediate layer film;

irradiating a predetermined region of the photoresist layer with radiation for development, thereby forming a resist pattern;

etching the intermediate layer film with the resist pattern as a mask;

etching the underlayer film with the obtained intermediate layer film pattern as an etching mask; and etching the substrate with the obtained underlayer film pattern as an etching mask, thereby forming a pattern on the substrate.

### Advantageous Effects of Invention

The present invention can provide a film forming material for lithography that is applicable to a wet process, and is useful for forming a photoresist underlayer film excellent in sublimation resistance and film heat resistance during baking at a high temperature, embedding properties to a substrate having difference in level, and film flatness; a composition for film formation for lithography comprising the material; as well as an underlayer film for lithography and a method for forming a pattern by using the composition.

### DESCRIPTION OF EMBODIMENTS

Hereinafter, embodiments of the present invention will be described. The embodiments described below are given merely for illustrating the present invention. The present invention is not limited only by these embodiments.

A film forming material for lithography in the present embodiment comprises a maleimide resin represented by the following formula (1A).

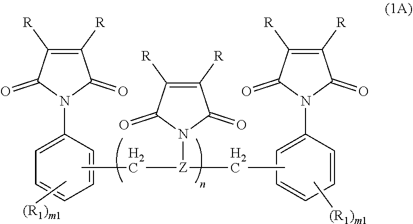

(In formula (1A),

each R is independently any one group selected from the group consisting of a hydrogen atom and an alkyl group having 1 to 4 carbon atoms;

each Z is independently a trivalent or tetravalent hydrocarbon group having 1 to 100 carbon atoms and optionally containing a heteroatom;

each R₁ is independently a group having 0 to 10 carbon atoms and optionally containing a heteroatom;

each m1 is independently an integer of 0 to 4; and

n is an integer of 1 or more.)

Each R is independently any one group selected from the group consisting of a hydrogen atom and an alkyl group having 1 to 4 carbon atoms. R is preferably a hydrogen atom from the viewpoint of the availability of raw materials and ease of production.

Each Z is independently a trivalent or tetravalent hydrocarbon group having 1 to 100 carbon atoms and optionally containing a heteroatom. Examples of Z include, for example, a phenyl ring and a biphenyl ring. Z is preferably a phenyl ring from the viewpoint of heat resistance.

Each R₁ is independently a group having 0 to 10 carbon atoms and optionally containing a heteroatom (for example, oxygen, nitrogen, sulfur, fluorine, chlorine, bromine, iodine). In addition, R₁ is preferably a hydrocarbon group from the viewpoint of improvement in solubility in an organic solvent. For example, examples of R₁ include an alkyl group (for example, an alkyl group having 1 to 6 or 1 to 3 carbon atoms), and specific examples thereof include a methyl group and an ethyl group.

Each m1 is independently an integer of 0 to 4. In addition, m1 is preferably 0 or 1, and is more preferably 0 from the viewpoint of the availability of raw materials.

n is an integer of 1 or more. In addition, from the viewpoint of film heat resistance, n is preferably an integer of 1 to 10, and from the viewpoint of film flatness, it is more preferably an integer of 1 to 4 and is still more preferably 1. Also, from the viewpoint of film formation, it is more preferably an integer of 1 to 4, and is still more preferably 1.

From the viewpoint of film heat resistance during baking at a high temperature, the content of the maleimide resin in the film forming material for lithography of the present embodiment is preferably 51 to 100% by mass, more preferably 60 to 100% by mass, still more preferably 70 to 100% by mass, and particularly preferably 80 to 100% by mass.

The maleimide resin in the film forming material for lithography of the present embodiment can be used as an additive agent in order to improve the heat resistance of a conventional underlayer film forming composition. In that case, the content of the maleimide compound is preferably 1 to 50% by mass and more preferably 1 to 30% by mass.

Examples of the conventional underlayer film forming composition include, but are not limited to, those descried in International Publication No. WO 2013/024779, for example.

The maleimide resin in the film forming material for lithography of the present embodiment has a function different from that of an acid generating agent for film formation for lithography or of a basic compound.

It is preferable that the molecular weight of the maleimide resin of the present embodiment be 500 or more. When the molecular weight is 500 or more, the production of sublimates or decomposition products tends to be suppressed even with high temperature baking during thin film formation. From the same viewpoint, it is more preferable that the molecular weight of the maleimide resin be 600 or more.

Here, the molecular weight can be measured according to the method described in Examples below.

From the viewpoint of the availability of raw materials and heat resistance, it is preferable that the maleimide resin of the present embodiment have a structure represented by the following formula (2A) or the following formula (3A).

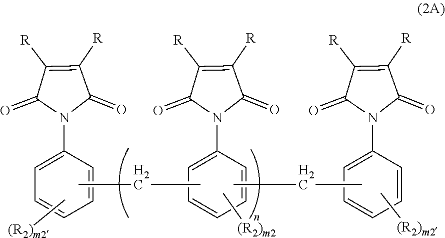

In the above formula (2A), R is as defined in the above formula (1A);

each R₂ is independently a group having 0 to 10 carbon atoms and optionally containing a heteroatom (for example, oxygen, nitrogen, sulfur, fluorine, chlorine, bromine, iodine). In addition, R₂ is preferably a hydrocarbon group from the viewpoint of improvement in solubility in an organic solvent. For example, examples of R₂ include an alkyl group (for example, an alkyl group having 1 to 6 or 1 to 3 carbon atoms) and specific examples thereof include a methyl group and an ethyl group.

Each m2 is independently an integer of 0 to 3. In addition, m2 is preferably 0 or 1, and is more preferably 0 from the viewpoint of the availability of raw materials.

Each m2′ is independently an integer of 0 to 4. In addition, m2′ is preferably 0 or 1, and is more preferably 0 from the viewpoint of the availability of raw materials.

n is an integer of 1 or more. In addition, from the viewpoint of film heat resistance, n is preferably an integer of 1 to 10, and from the viewpoint of film flatness, n is more preferably an integer of 1 to 4 and is still more preferably 1. Also, from the viewpoint of film formation, n is more preferably an integer of 1 to 4, and is still more preferably 1.

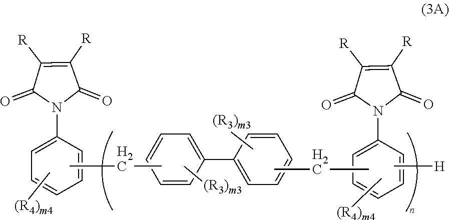

In the above formula (3A), R is as defined in the above formula (1A);

R₃ and R₄ are each independently a group having 0 to 10 carbon atoms and optionally containing a heteroatom (for example, oxygen, nitrogen, sulfur, fluorine, chlorine, bromine, iodine). In addition, R₃ and R₄ are preferably hydrocarbon groups from the viewpoint of improvement in solubility in an organic solvent. For example, examples of R₃ and R₄ include an alkyl group (for example, an alkyl group having 1 to 6 or 1 to 3 carbon atoms), and specific examples thereof include a methyl group and an ethyl group.

Each m3 is independently an integer of 0 to 4. In addition, m3 is preferably an integer of 0 to 2, and is more preferably 0 from the viewpoint of the availability of raw materials.

Each m4 is independently an integer of 0 to 4. In addition, m4 is preferably an integer of 0 to 2, and is more preferably 0 from the viewpoint of the availability of raw materials.

n is an integer of 2 or more. In addition, from the viewpoint of film heat resistance, n is preferably an integer of 2 to 10, and from the viewpoint of film flatness, n is more preferably an integer of 2 to 4 and is still more preferably 2. Also, from the viewpoint of film formation, n is more preferably an integer of 2 to 4, and is still more preferably 2.

From the viewpoint of the availability of raw materials, the heteroatom in the formulas (1A) to (3A) mentioned above is preferably any one selected from the group consisting of oxygen, fluorine, and silicon.

The film forming material for lithography of the present embodiment is applicable to a wet process. In addition, since the film forming material for lithography of the present embodiment is a resin having a rigid aromatic maleimide skeleton and further comprising components with a certain molecular weight or more, the production of sublimates or decomposition products is suppressed even with high temperature baking during thin film formation. As a result, deterioration of the film upon baking at a high temperature is suppressed and an underlayer film excellent in etching resistance can be formed. Furthermore, even though the film forming material for lithography of the present embodiment has an aromatic structure, its solubility in an organic solvent is high and its solubility in a safe solvent is high. Furthermore, an underlayer film for lithography composed of the composition for film formation for lithography of the present embodiment, which will be mentioned later, is not only excellent in embedding properties to a substrate having difference in level and film flatness, thereby having a good stability of the product quality, but also excellent in adhesiveness to a resist layer or a resist intermediate layer film material, and thus, an excellent resist pattern can be obtained.

As the maleimide resin in the present embodiment, although there is no particular limitation, an addition polymerization maleimide resin is suitably used. Examples of the addition polymerization maleimide resin include, for example, Bismaleimide M-20 (manufactured by Mitsui Chemicals, Inc., trade name), BMI-2300 (manufactured by Daiwa Kasei Industry Co., Ltd., trade name), BMI-3200 (manufactured by Daiwa Kasei Industry Co., Ltd., trade name), MIR-3000 (manufactured by Nippon Kayaku Co., Ltd., product name), and high molecular weight polymers thereof.

In addition, as the maleimide resin in the present embodiment, it is preferable to use a citraconimide resin from the viewpoint of compatibility of heat resistance and solubility, and a BMI citraconimide resin and a high molecular weight polymer thereof, a BAN citraconimide resin and a high molecular weight polymer thereof, and the like can be used.

Here, the high molecular weight polymer refers to the resin composition from which the monomer component has been selectively removed.

### <Crosslinking Agent>

The film forming material for lithography of the present embodiment may comprise a crosslinking agent, if required, in addition to the maleimide resin, from the viewpoint of lowering the curing temperature, suppressing intermixing, and the like.

The crosslinking agent is not particularly limited as long as it undergoes a crosslinking reaction with the maleimide resin, and any of publicly known crosslinking agents can be applied. Specific examples of the crosslinking agent include, but are not particularly limited to, a phenol compound, an allyl compound, a propenyl compound, an epoxy compound, a cyanate compound, an amino compound, a benzoxazine compound, an acrylate compound, a melamine compound, a guanamine compound, a glycoluril compound, a urea compound, an isocyanate compound, and an azide compound. These crosslinking agents can be used alone as one kind, or can be used in combination of two or more kinds. Among them, a benzoxazine compound, an epoxy compound, or a cyanate compound is preferable, and a benzoxazine compound is more preferable from the viewpoint of improvement in film resistance.

In a crosslinking reaction between the maleimide resin and the crosslinking agent, for example, an active group these crosslinking agents have (a phenolic hydroxy group, an allyl group, a propenyl group, an epoxy group, a cyanate group, an amino group, or a phenolic hydroxy group formed by ring opening of the alicyclic site of benzoxazine) undergoes an addition reaction with a carbon-carbon double bond that constitutes a maleimide group to form crosslinkage. Besides, two carbon-carbon double bonds that the maleimide resin of the present embodiment has are polymerized to form crosslinkage.

As the above phenol compound, a publicly known compound can be used. Examples of the phenol include, for example, phenol, as well as an alkylphenol such as a cresol and a xylenol, a polyhydric phenol such as hydroquinone, a polycyclic phenol such as a naphthol and a naphthalenediol, a bisphenol such as bisphenol A and bisphenol F, and a polyfunctional phenol compound such as phenol novolac and a phenol aralkyl resin. Among the above, an aralkyl-based phenolic resin is preferable from the viewpoint of heat resistance and solubility.

As the above propenyl compound, a publicly known compound can be used, and specific examples thereof include, for example, 1-propenylbenzene, 1-methoxy-4-(1-propenyl)benzene, 1,2-diphenylethene (stilbene), 4-propenyl-phenol, a diphenylmethane-based propenylphenolic resin. Among the above, a diphenylmethane-based propenylphenolic resin is preferable from the viewpoint of improvement in heat resistance.

As the above epoxy compound, a publicly known compound can be used and is selected from among compounds having two or more epoxy groups in one molecule. Examples thereof include, for example, epoxidation products of dihydric phenols such as bisphenol A, bisphenol F, 3,3′,5,5′-tetramethyl-bisphenol F, bisphenol S, fluorene bisphenol, 2,2′-biphenol, 3,3′,5,5′-tetramethyl-4,4′-dihydroxybiphenol, resorcin, and naphthalenediols; epoxidation products of trihydric or higher phenols such as tris-(4-hydroxyphenyl)methane, 1,1,2,2-tetrakis(4-hydroxyphenyl)ethane, tris(2,3-epoxypropyl) isocyanurate, trimethylolmethane triglycidyl ether, trimethylolpropane triglycidyl ether, triethylolethane triglycidyl ether, phenol novolac, and o-cresol novolac; epoxidation products of co-condensed resins of dicyclopentadiene and phenols; epoxidation products of phenol aralkyl resins synthesized from phenols and paraxylylene dichloride; epoxidation products of biphenyl aralkyl-based phenolic resins synthesized from phenols and bischloromethylbiphenyl; epoxidation products of naphthol aralkyl resins synthesized from naphthols and paraxylylene dichloride. These epoxy resins may be used alone, or may be used in combination of two or more kinds. Among the above, an epoxy resin that is in a solid state at normal temperature, such as an epoxy resin obtained from a phenol aralkyl resin or a biphenyl aralkyl resin is preferable from the viewpoint of heat resistance and solubility.

The above cyanate compound is not particularly limited as long as the compound has two or more cyanate groups in one molecule, and a publicly known compound can be used. For example, examples thereof include those described in International Publication No. WO 2011/108524. Preferable examples of the cyanate compound include those having a structure where hydroxy groups of a compound having two or more hydroxy groups in one molecule are substituted with cyanate groups. Also, the cyanate compound preferably has an aromatic group, and those having a structure in which a cyanate group is directly bonded to the aromatic group can be suitably used. Examples of such a cyanate compound include, for example, those having a structure where hydroxy groups of bisphenol A, bisphenol F, bisphenol M, bisphenol P, bisphenol E, a phenol novolac resin, a cresol novolac resin, a dicyclopentadiene novolac resin, tetramethylbisphenol F, a bisphenol A novolac resin, brominated bisphenol A, a brominated phenol novolac resin, trifunctional phenol, tetrafunctional phenol, naphthalene-based phenol, biphenyl-based phenol, a phenol aralkyl resin, a biphenyl aralkyl resin, a naphthol aralkyl resin, a dicyclopentadiene aralkyl resin, alicyclic phenol, phosphorus-containing phenol, or the like are substituted with cyanate groups. These cyanate compounds may be used alone, or may be used in arbitrary combination of two or more kinds. Also, the above cyanate compound may be in any form of a monomer, an oligomer and a resin.

Examples of the above amino compound include m-phenylenediamine, p-phenylenediamine, 4,4′-diaminodiphenylmethane, 4,4′-diaminodiphenylpropane, 4,4′-diaminodiphenyl ether, 3,4′-diaminodiphenyl ether, 3,3′-diaminodiphenyl ether, 4,4′-diaminodiphenylsulfone, 3,4′-diaminodiphenylsulfone, 3,3′-diaminodiphenylsulfone, 4,4′-diaminodiphenyl sulfide, 3,4′-diaminodiphenyl sulfide, 3,3′-diaminodiphenyl sulfide, 1,4-bis(4-aminophenoxy)benzene, 1,3-bis(4-aminophenoxy)benzene, 1,4-bis(3-aminophenoxy)benzene, 1,3-bis(3-aminophenoxy)benzene, bis[4-(4-aminophenoxy)phenyl]sulfone, 2,2-bis[4-(4-aminophenoxy)phenyl]propane, 2,2-bis[4-(3-aminophenoxy)phenyl]propane, 4,4′-bis(4-aminophenoxy)biphenyl, 4,4′-bis(3-aminophenoxy)biphenyl, bis[4-(4-aminophenoxy)phenyl] ether, bis[4-(3-aminophenoxy)phenyl] ether, 9,9-bis(4-aminophenyl)fluorene, 9,9-bis(4-amino-3-chlorophenyl)fluorene, 9,9-bis(4-amino-3-fluorophenyl)fluorene, 0-tolidine, m-tolidine, 4,4′-diaminobenzanilide, 2,2′-bis(trifluoromethyl)-4,4′-diaminobiphenyl, 4-aminophenyl-4-aminobenzoate, 2-(4-aminophenyl)-6-aminobenzoxazole. Among them, examples thereof include aromatic amines such as 4,4′-diaminodiphenylmethane, 4,4′-diaminodiphenylpropane, 4,4′-diaminodiphenyl ether, 3,4′-diaminodiphenyl ether, 3,3′-diaminodiphenyl ether, 4,4′-diaminodiphenylsulfone, 3,3′-diaminodiphenylsulfone, 1,4-bis(4-aminophenoxy)benzene, 1,3-bis(4-aminophenoxy)benzene, 1,4-bis(3-aminophenoxy)benzene, 1,3-bis(3-aminophenoxy)benzene, bis[4-(4-aminophenoxy)phenyl]sulfone, 2,2-bis[4-(4-aminophenoxy)phenyl]propane, 2,2-bis[4-(3-aminophenoxy)phenyl]propane, 4,4′-bis(4-aminophenoxy)biphenyl, 4,4′-bis(3-aminophenoxy)biphenyl, bis[4-(4-aminophenoxy)phenyl] ether, and bis[4-(3-aminophenoxy)phenyl] ether; alicyclic amines such as diaminocyclohexane, diaminodicyclohexylmethane, dimethyl-diaminodicyclohexylmethane, tetramethyl-diaminodicyclohexylmethane, diaminodicyclohexylpropane, diaminobicyclo[2.2.1]heptane, bis(aminomethyl)-bicyclo[2.2.1]heptane, 3(4),8(9)-bis(aminomethyl)tricyclo[5.2.1.02,6]decane, 1,3-bisaminomethylcyclohexane, and isophoronediamine; aliphatic amines such as ethylenediamine, hexamethylenediamine, octamethylenediamine, decamethylenediamine, diethylenetriamine, and triethylenetetramine.

The structure of oxazine of the above benzoxazine compound is not particularly limited, and examples thereof include a structure of oxazine having an aromatic group including a condensed polycyclic aromatic group, such as benzoxazine and naphthoxazine.

Examples of the benzoxazine compound include, for example, compounds represented by the following general formulas (a) to (f). Note that, in the general formulas described below, a bond displayed toward the center of a ring indicates a bond to any carbon that constitutes the ring and to which a substituent can be bonded.

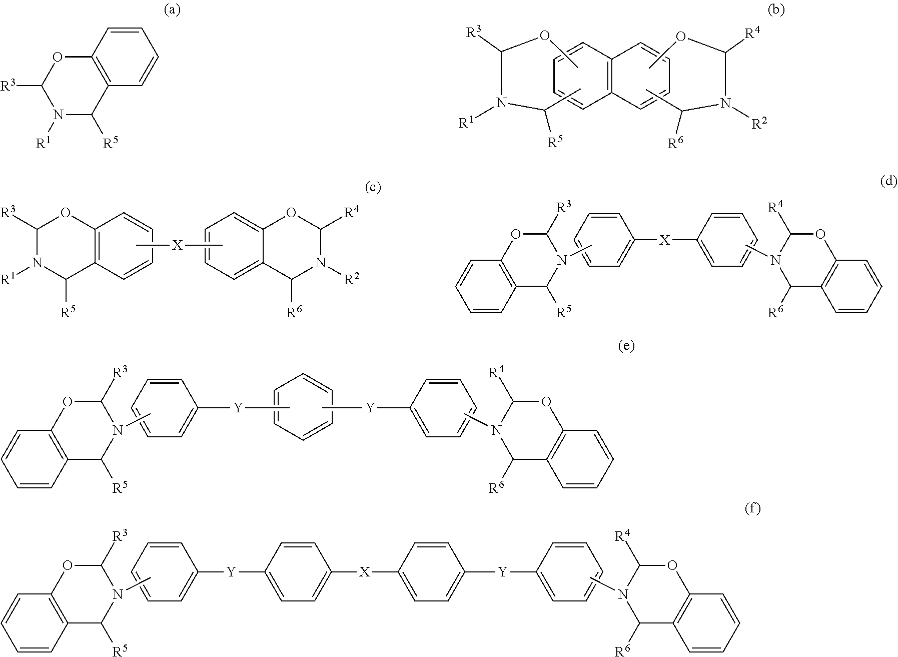

In the general formulas (a) to (c), R¹ and R² each independently represent an organic group having 1 to 30 carbon atoms. In addition, in the general formulas (a) to (f), R³ to R⁶ each independently represent hydrogen or a hydrocarbon group having 1 to 6 carbon atoms. Moreover, in the above general formulas (c), (d), and (f), X independently represents a single bond, —O—, —S—, —S—S—, —SO₂—, —CO—, —CONH—, —NHCO—, —C(CH₃)₂—, —C(CF₃)₂—, —(CH₂)m-, —O—(CH₂)m-O—, or —S—(CH₂)m-S—. Here, m is an integer of 1 to 6. In addition, in the general formulas (e) and (f), Y independently represents a single bond, —O—, —S—, —CO—, —C(CH₃)₂—, —C(CF₃)₂—, or alkylene having 1 to 3 carbon atoms.

Moreover, the benzoxazine compound includes an oligomer or polymer having an oxazine structure as a side chain, and an oligomer or polymer having a benzoxazine structure in the main chain.

The benzoxazine compound can be produced in a similar method as a method described in International Publication No. WO 2004/009708, Japanese Patent Application Laid-Open No. 11-12258, or Japanese Patent Application Laid-Open No. 2004-352670.

As the above acrylate compound, a publicly known compound can be used, and examples thereof include, for example, alkyl (meth)acrylates with an alkyl group having 1 to 22 carbon atoms such as methyl (meth)acrylate, ethyl (meth)acrylate, n-propyl (meth)acrylate, n-butyl (meth)acrylate, isobutyl (meth)acrylate, tert-butyl (meth)acrylate, 2-ethylhexyl (meth)acrylate, and lauryl (meth)acrylate; aralkyl (meth)acrylates such as benzyl (meth)acrylate and 2-phenylethyl (meth)acrylate; cycloalkyl (meth)acrylates such as cyclohexyl (meth)acrylate and isobornyl (meth)acrylate; o-alkoxyalkyl (meth)acrylates such as 2-methoxyethyl (meth)acrylate and 4-methoxybutyl (meth)acrylate. Among the above, aralkyl (meth)acrylates such as benzyl (meth)acrylate and 2-phenylethyl (meth)acrylate are preferable from the viewpoint of heat resistance of the cured product.

Specific examples of the above melamine compound include, for example, hexamethylolmelamine, hexamethoxymethylmelamine, a compound in which 1 to 6 methylol groups of hexamethylolmelamine are methoxymethylated or a mixture thereof, hexamethoxyethylmelamine, hexaacyloxymethylmelamine, and a compound in which 1 to 6 methylol groups of hexamethylolmelamine are acyloxymethylated or a mixture thereof.

Specific examples of the above guanamine compound include, for example, tetramethylolguanamine, tetramethoxymethylguanamine, a compound in which 1 to 4 methylol groups of tetramethylolguanamine are methoxymethylated or a mixture thereof, tetramethoxyethylguanamine, tetraacyloxyguanamine, and a compound in which 1 to 4 methylol groups of tetramethylolguanamine are acyloxymethylated or a mixture thereof.

Specific examples of the above glycoluril compound include, for example, tetramethylolglycoluril, tetramethoxyglycoluril, tetramethoxymethylglycoluril, a compound in which 1 to 4 methylol groups of tetramethylolglycoluril are methoxymethylated or a mixture thereof, and a compound in which 1 to 4 methylol groups of tetramethylolglycoluril are acyloxymethylated or a mixture thereof.

Specific examples of the above urea compound include, for example, tetramethylolurea, tetramethoxymethylurea, a compound in which 1 to 4 methylol groups of tetramethylolurea are methoxymethylated or a mixture thereof, and tetramethoxyethylurea.

As the above isocyanate compound, a publicly known compound can be used, and examples thereof include, for example, tolylene diisocyanate, diphenylmethane diisocyanate, hexamethylene diisocyanate, and cyclohexane diisocyanate. Among the above, tolylene diisocyanate is preferable from the viewpoint of heat resistance.

As the above azide compound, a publicly known compound can be used, and examples thereof include, for example, 1,1′-biphenyl-4,4′-bisazide, 4,4′-methylidene bisazide, 4,4′-oxy bisazide, and the like. Among the above, 1,1′-biphenyl-4,4′-bisazide is preferable from the viewpoint of availability.

In the present embodiment, a crosslinking agent having at least one allyl group may be used from the viewpoint of improvement in crosslinkability. Specific examples of the crosslinking agent having at least one allyl group include, but are not limited to, allylphenols such as 2,2-bis(3-allyl-4-hydroxyphenyl)propane, 1,1,1,3,3,3-hexafluoro-2,2-bis(3-allyl-4-hydroxyphenyl)propane, bis(3-allyl-4-hydroxyphenyl)sulfone, bis(3-allyl-4-hydroxyphenyl) sulfide, and bis(3-allyl-4-hydroxyphenyl) ether; allyl cyanates such as 2,2-bis(3-allyl-4-cyanatephenyl)propane, 1,1,1,3,3,3-hexafluoro-2,2-bis(3-allyl-4-cyanatephenyl)propane, bis(3-allyl-4-cyanatephenyl)sulfone, bis(3-allyl-4-cyanatephenyl) sulfide, and bis(3-allyl-4-cyanatephenyl) ether; diallyl phthalate, diallyl isophthalate, diallyl terephthalate, triallyl isocyanurate, trimethylolpropane diallyl ether, and pentaerythritol allyl ether. These crosslinking agents having at least one allyl group may be alone, or may be a mixture of two or more kinds. Among them, an allylphenol such as 2,2-bis(3-allyl-4-hydroxyphenyl)propane, 1,1,1,3,3,3-hexafluoro-2,2-bis(3-allyl-4-hydroxyphenyl)propane, bis(3-allyl-4-hydroxyphenyl)sulfone, bis(3-allyl-4-hydroxyphenyl)sulfide, and bis(3-allyl-4-hydroxyphenyl) ether is preferable from the viewpoint of excellent compatibility with the maleimide resin.

With the film forming material for lithography of the present embodiment, the film for lithography of the present embodiment can be formed by crosslinking and curing the maleimide resin alone, or after compounding with the above crosslinking agent, by a publicly known method. Examples of the crosslinking method include approaches such as heat curing and light curing.

The content ratio of the crosslinking agent is normally in the range of 0.1 to 10000 parts by mass based on 100 parts by mass of the total mass of the above maleimide resin, preferably in the range of 0.1 to 1000 parts by mass from the viewpoint of heat resistance and solubility, more preferably in the range of 0.1 to 100 parts by mass, still more preferably in the range of 1 to 50 parts by mass, and particularly preferably in the range of 1 to 30 parts by mass.

### <Crosslinking Promoting Agent>

In the film forming material for lithography of the present embodiment, if required, a crosslinking promoting agent for accelerating crosslinking reaction and curing reaction can be used.

The above crosslinking promoting agent is not particularly limited as long as it accelerates crosslinking or curing reaction, and examples thereof include an amine, an imidazole, an organic phosphine, and a Lewis acid. These crosslinking promoting agents can be used alone as one kind, or can be used in combination of two or more kinds. Among them, an imidazole or an organic phosphine is preferable, and an imidazole is more preferable from the viewpoint of decrease in crosslinking temperature.

Examples of the above crosslinking promoting agent include, but are not limited to, for example, tertiary amines such as 1,8-diazabicyclo(5,4,0)undecene-7, triethylenediamine, benzyldimethylamine, triethanolamine, dimethylaminoethanol, and tris(dimethylaminomethyl)phenol; imidazoles such as 2-methylimidazole, 2-phenylimidazole, 2-ethyl-4-methylimidazole, 2-phenyl-4-methylimidazole, 2-heptadecylimidazole, and 2,4,5-triphenylimidazole; organic phosphines such as tributylphosphine, methyldiphenylphosphine, triphenylphosphine, diphenylphosphine, and phenylphosphine; tetra substituted phosphonium-tetra substituted borates such as tetraphenylphosphonium-tetraphenyl borate, tetraphenylphosphonium-ethyltriphenyl borate, and tetrabutylphosphonium-tetrabutyl borate; and tetraphenylboron salts such as 2-ethyl-4-methylimidazole-tetraphenyl borate and N-methylmorpholine-tetraphenyl borate.

The content of the crosslinking promoting agent is normally preferably in the range of 0.1 to 10 parts by mass based on 100 parts by mass of the total mass of the maleimide resin in the present embodiment, and is more preferably in the range of 0.1 to 5 parts by mass and still more preferably in the range of 0.1 to 3 parts by mass, from the viewpoint of easy control and cost efficiency.

### <Radical Polymerization Initiator>

The film forming material for lithography of the present embodiment can contain, if required, a radical polymerization initiator. The radical polymerization initiator may be a photopolymerization initiator that initiates radical polymerization by light, or may be a thermal polymerization initiator that initiates radical polymerization by heat.

Such a radical polymerization initiator is not particularly limited, and a radical polymerization initiator conventionally used can be arbitrarily employed. Examples thereof include, for example, ketone-based photopolymerization initiators such as 1-hydroxy cyclohexyl phenyl ketone, benzyl dimethyl ketal, 2-hydroxy-2-methyl-1-phenylpropan-1-one, 1-[4-(2-hydroxyethoxy)-phenyl]-2-hydroxy-2-methyl-1-propan-1-one, 2-hydroxy-1-{4-[4-(2-hydroxy-2-methyl-propionyl)-benzyl]phenyl}-2-methylpropan-1-one, 2,4,6-trimethylbenzoyl-diphenyl-phosphine oxide, and bis(2,4,6-trimethylbenzoyl)-phenylphosphine oxide; and organic peroxide-based polymerization initiators such as methyl ethyl ketone peroxide, cyclohexanone peroxide, methylcyclohexanone peroxide, methyl acetoacetate peroxide, acetyl acetate peroxide, 1,1-bis(t-hexylperoxy)-3,3,5-trimethylcyclohexane, 1,1-bis(t-hexylperoxy)-cyclohexane, 1,1-bis(t-butylperoxy)-3,3,5-trimethylcyclohexane, 1,1-bis(t-butylperoxy)-2-methylcyclohexane, 1,1-bis(t-butylperoxy)-cyclohexane, 1,1-bis(t-butylperoxy)cyclododecane, 1,1-bis(t-butylperoxy)butane, 2,2-bis(4,4-di-t-butylperoxycyclohexyl)propane, p-menthane hydroperoxide, diisopropylbenzene hydroperoxide, 1,1,3,3-tetramethylbutyl hydroperoxide, cumene hydroperoxide, t-hexyl hydroperoxide, t-butyl hydroperoxide, α,α′-bis(t-butylperoxy)diisopropylbenzene, dicumyl peroxide, 2,5-dimethyl-2,5-bis(t-butylperoxy)hexane, t-butylcumyl peroxide, di-t-butyl peroxide, 2,5-dimethyl-2,5-bis(t-butylperoxy)hexyne-3, isobutyryl peroxide, 3,5,5-trimethylhexanoyl peroxide, octanoyl peroxide, lauroyl peroxide, stearoyl peroxide, succinic acid peroxide, m-toluoyl benzoyl peroxide, benzoyl peroxide, di-n-propyl peroxydicarbonate, diisopropyl peroxydicarbonate, bis(4-t-butylcyclohexyl) peroxydicarbonate, di-2-ethoxyethyl peroxydicarbonate, di-2-ethoxyhexyl peroxydicarbonate, di-3-methoxybutyl peroxydicarbonate, di-s-butyl peroxydicarbonate, di(3-methyl-3-methoxybutyl) peroxydicarbonate, α,α′-bis(neodecanoylperoxy)diisopropylbenzene, cumyl peroxyneodecanoate, 1,1,3,3-tetramethylbutyl peroxyneodecanoate, 1-cyclohexyl-1-methylethyl peroxyneodecanoate, t-hexyl peroxyneodecanoate, t-butyl peroxyneodecanoate, t-hexyl peroxypivalate, t-butyl peroxypivalate, 1,1,3,3-tetramethylbutyl peroxy-2-ethylhexanoate, 2,5-dimethyl-2,5-bis(2-ethylhexanoylperoxy)hexanoate, 1-cyclohexyl-1-methylethyl peroxy-2-ethylhexanoate, t-hexyl peroxy-2-ethylhexanoate, t-butyl peroxy-2-ethylhexanoate, t-hexyl peroxyisopropylmonocarbonate, t-butyl peroxyisobutyrate, t-butyl peroxymalate, t-butyl peroxy-3,5,5-trimethylhexanoate, t-butyl peroxylaurate, t-butyl peroxyisopropylmonocarbonate, t-butyl peroxy-2-ethylhexylmonocarbonate, t-butyl peroxyacetate, t-butyl peroxy-m-toluylbenzoate, t-butyl peroxybenzoate, bis(t-butylperoxy) isophthalate, 2,5-dimethyl-2,5-bis (m-toluylperoxy)hexane, t-hexyl peroxybenzoate, 2,5-dimethyl-2,5-bis(benzoylperoxy)hexane, t-butyl peroxyallylmonocarbonate, t-butyltrimethylsilyl peroxide, 3,3′,4,4′-tetra(t-butylperoxycarbonyl)benzophenone, and 2,3-dimethyl-2,3-diphenylbutane.

Further examples thereof include azo-based polymerization initiators such as 2-phenylazo-4-methoxy-2,4-dimethylvaleronitrile, 1-[(1-cyano-1-methylethyl)azo]formamide, 1,1′-azobis(cyclohexane-1-carbonitrile), 2,2′-azobis(2-methylbutyronitrile), 2,2′-azobisisobutyronitrile, 2,2′-azobis(2,4-dimethylvaleronitrile), 2,2′-azobis(2-methylpropionamidine) dihydrochloride, 2,2′-azobis(2-methyl-N-phenylpropionamidine) dihydrochloride, 2,2′-azobis[N-(4-chlorophenyl)-2-methylpropionamidine]dihydride chloride, 2,2′-azobis[N-(4-hydrophenyl)-2-methylpropionamidine] dihydrochloride, 2,2′-azobis[2-methyl-N-(phenylmethyl)propionamidine]dihydrochloride, 2,2′-azobis[2-methyl-N-(2-propenyl)propionamidine] dihydrochloride, 2,2′-azobis[N-(2-hydroxyethyl)-2-methylpropionamidine] dihydrochloride, 2,2′-azobis[2-(5-methyl-2-imidazolin-2-yl)propane]dihydrochloride, 2,2′-azobis[2-(2-imidazolin-2-yl)propane] dihydrochloride, 2,2′-azobis[2-(4,5,6,7-tetrahydro-1H-1,3-diazepin-2-yl)propane] dihydrochloride, 2,2′-azobis[2-(3,4,5,6-tetrahydropyrimidin-2-yl)propane]dihydrochloride, 2,2′-azobis[2-(5-hydroxy-3,4,5,6-tetrahydropyrimidin-2-yl)propane] dihydrochloride, 2,2′-azobis[2-[1-(2-hydroxyethyl)-2-imidazolin-2-yl]propane]dihydrochloride, 2,2′-azobis[2-(2-imidazolin-2-yl)propane], 2,2′-azobis[2-methyl-N-[1,1-bis(hydroxymethyl)-2-hydroxyethyl]propionamide], 2,2′-azobis[2-methyl-N-[1,1-bis(hydroxymethyl)ethyl]propionamide], 2,2′-azobis[2-methyl-N-(2-hydroxyethyl)propionamide], 2,2′-azobis(2-methylpropionamide), 2,2′-azobis(2,4,4-trimethylpentane), 2,2′-azobis(2-methylpropane), dimethyl-2,2-azobis(2-methylpropionate), 4,4′-azobis(4-cyanopentanoic acid), and 2,2′-azobis[2-(hydroxymethyl)propionitrile]. As the radical polymerization initiator in the present embodiment, one kind thereof may be used alone, or two or more kinds may be used in combination. Alternatively, the radical polymerization initiator in the present embodiment may be used in further combination with an additional publicly known polymerization initiator.

The content of the above radical polymerization initiator may be any amount as long as it is a stoichiometrically required amount relative to the total mass of the above maleimide resin, but it is preferably 0.05 to 25 parts by mass and more preferably 0.1 to 10 parts by mass, based on 100 parts by mass of the total mass of the above maleimide resin. When the content of the radical polymerization initiator is 0.05 parts by mass or more, there is a tendency that curing of the maleimide resin can be prevented from being insufficient. Meanwhile, when the content of the radical polymerization initiator is 25 parts by mass or less, there is a tendency that the long term storage stability of the film forming material for lithography at room temperature can be prevented from being impaired.

### [Composition for Film Formation for Lithography]

A composition for film formation for lithography of the present embodiment comprises the above film forming material for lithography and a solvent. The film for lithography is, for example, an underlayer film for lithography.

The composition for film formation for lithography of the present embodiment can form a desired cured film by applying it on a base material, subsequently heating it to evaporate the solvent if necessary, and then heating or photoirradiating it. A method for applying the composition for film formation for lithography of the present embodiment is arbitrary, and a method such as spin coating, dipping, flow coating, inkjet coating, spraying, bar coating, gravure coating, slit coating, roll coating, transfer printing, brush coating, blade coating, and air knife coating can be employed appropriately.

The temperature at which the film is heated is not particularly limited according to the purpose of evaporating the solvent, and the heating can be carried out at, for example, 40 to 600° C. A method for heating is not particularly limited, and for example, the solvent may be evaporated under an appropriate atmosphere such as atmospheric air, an inert gas including nitrogen, and vacuum by using a hot plate or an oven. For the heating temperature and heating time, it is only required to select conditions suitable for a processing step for an electronic device that is aimed at and to select heating conditions by which physical property values of the obtained film satisfy requirements of the electronic device. Conditions for photoirradiation are not particularly limited, either, and it is only required to employ appropriate irradiation energy and irradiation time depending on a film forming material for lithography to be used.

### <Solvent>

A solvent to be used in the composition for film formation for lithography of the present embodiment is not particularly limited as long as it can at least dissolve the above maleimide resin, and any publicly known solvent can be used appropriately.

Specific examples of the solvent include, for example, those described in International Publication No. WO 2013/024779. These solvents can be used alone as one kind, or can be used in combination of two or more kinds.

Among the above solvents, cyclohexanone, cyclopentanone, propylene glycol monomethyl ether, propylene glycol monomethyl ether acetate, ethyl lactate, methyl hydroxyisobutyrate, butyl acetate, or y-butyrolactone is particularly preferable from the viewpoint of safety.

The content of the above solvent is not particularly limited and is preferably 25 to 9,900 parts by mass, more preferably 400 to 7,900 parts by mass, and still more preferably 900 to 4,900 parts by mass based on 100 parts by mass of the total mass of the maleimide resin in the material for film formation for lithography, from the viewpoint of solubility and film formation.

### <Base Generating Agent>

The film forming material for lithography of the present embodiment can contain, if required, a base generating agent. Due to the structural characteristics of the compounds that can be used in the present embodiment, a latent base generating agent is preferable. Those generating a base by thermal decomposition, those generating a base by light irradiation, and the like are known, any of which can be used.

Specific examples of the base generating agent include, but are not limited to, the following.

### Examples of hexaammineruthenium(III) Triphenylalkylborate

Hexaammineruthenium(III) tris(triphenylmethylborate), hexaammineruthenium(III) tris(triphenylethylborate), hexaammineruthenium(III) tris(triphenylpropylborate), hexaammineruthenium(III) tris(triphenylbutylborate), hexaammineruthenium(III) tris(triphenylhexylborate), hexaammineruthenium(III) tris(triphenyloctylborate), hexaammineruthenium(III) tris(triphenyloctadecylborate), hexaammineruthenium(III) tris(triphenylisopropylborate), hexaammineruthenium(III) tris(triphenylisobutylborate), hexaammineruthenium(III) tris(triphenyl-sec-butylborate), hexaammineruthenium(III) tris(triphenyl-tert-butylborate), hexaammineruthenium(III) tris (triphenylneopentylborate), and the like.

### Examples of hexaammineruthenium(III) Triphenylborate

Hexaammineruthenium(III) tris(triphenylcyclopentylborate), hexaammineruthenium(III) tris(triphenylcyclohexylborate), hexaammineruthenium(III) tris[triphenyl(4-decylcyclohexyl)borate], hexaammineruthenium(III) tris[triphenyl(fluoromethyl)borate], hexaammineruthenium(III) tris[triphenyl(chloromethyl)borate], hexaammineruthenium(III) tris[triphenyl(bromomethyl)borate], hexaammineruthenium(III) tris[triphenyl(trifluoromethyl)borate], hexaammineruthenium(III) tris[triphenyl(trichloromethyl)borate], hexaammineruthenium(III) tris[triphenyl(hydroxymethyl)borate], hexaammineruthenium(III) tris[triphenyl(carboxymethyl)borate], hexaammineruthenium(III) tris[triphenyl(cyanomethyl)borate], hexaammineruthenium(III) tris[triphenyl(nitromethyl)borate], hexaammineruthenium(III) tris[triphenyl(azidomethyl)borate], and the like.

### Examples of hexaammineruthenium(III) Triarylbutylborate

Hexaammineruthenium(III) tris[tris(1-naphthyl)butylborate], hexaammineruthenium(III) tris[tris(2-naphthyl)butylborate], hexaammineruthenium(III) tris[tris(o-tolyl)butylborate], hexaammineruthenium(III) tris[tris(m-tolyl)butylborate], hexaammineruthenium(III) tris[tris(p-tolyl)butylborate], hexaammineruthenium(III) tris[tris(2,3-xylyl)butylborate], hexaammineruthenium(III) tris[tris(2,5-xylyl)butylborate], and the like.

### Examples of ruthenium(III) tris(triphenylbutylborate)

Tris(ethylenediamine)ruthenium(III) tris(triphenylbutylborate), cis-diamminebis(ethylenediamine)ruthenium(III) tris(triphenylbutylborate), trans-diamminebis(ethylenediamine)ruthenium(III) tris(triphenylbutylborate), tris(trimethylenediamine)ruthenium(III) tris(triphenylbutylborate), tris(propylenediamine)ruthenium(III) tris(triphenylbutylborate), tetraammine{(−)(propylenediamine)}ruthenium(III) tris(triphenylbutylborate), tris(trans-1,2-cyclohexanediamine)ruthenium(III) tris(triphenylbutylborate), bis(diethylenetriamine)ruthenium(III) tris(triphenylbutylborate), bis(pyridine)bis(ethylenediamine)ruthenium(III) tris(triphenylbutylborate), bis(imidazole)bis(ethylenediamine)ruthenium(III) tris(triphenylbutylborate), and the like.

The base generating agents mentioned above can be readily produced by mixing a halide salt, sulfate salt, nitrate salt, acetate salt, or the like of each complex ion with an alkali metal borate salt in an appropriate solvent such as water, an alcohol, or a water-containing organic solvent. These halide salt, sulfate salt, nitrate salt, acetate salt, and the like of each complex ion, which are raw materials, are easily available as commercial products. Besides, the synthesis method therefor is described in, for example, New Experimental Chemistry Lecture Vol. 8 (Synthesis of Inorganic Compounds III), edited by The Chemical Society of Japan, Maruzen Co., Ltd., 1977, and the like.

The content of the above base generating agent may be any amount as long as it is a stoichiometrically required amount relative to the total mass of the above maleimide resin, but it is preferably 0.01 to 25 parts by mass and more preferably 0.01 to 10 parts by mass, based on 100 parts by mass of the total mass of the above maleimide resin. When the content of the base generating agent is 0.01 parts by mass or more, there is a tendency that curing of the film forming material for lithography can be prevented from being insufficient. Meanwhile, when the content of the base generating agent initiator is 25 parts by mass or less, there is a tendency that the long term storage stability of the film forming material for lithography at room temperature can be prevented from being impaired.

The composition for film formation for lithography of the present embodiment may further contain a publicly known additive agent. Examples of the publicly known additive agent include, but are not limited to, ultraviolet absorbers, antifoaming agents, colorants, pigments, nonionic surfactants, anionic surfactants, and cationic surfactants.

### [Method for Forming Underlayer Film for Lithography and Pattern]

The underlayer film for lithography of the present embodiment is formed by using the composition for film formation for lithography of the present embodiment.

A resist pattern formation method of the present embodiment has the steps of: forming an underlayer film on a substrate using the composition for film formation for lithography of the present embodiment (step (A-1)); forming at least one photoresist layer on the underlayer film (step (A-2)); and after the step (A-2), irradiating a predetermined region of the photoresist layer with radiation for development (step (A-3)).

Furthermore, a circuit pattern formation method of the present embodiment has the steps of: forming an underlayer film on a substrate using the composition for film formation for lithography of the present embodiment (step (B-1)); forming an intermediate layer film on the underlayer film using a resist intermediate layer film material containing a silicon atom (step (B-2)); forming at least one photoresist layer on the intermediate layer film (step (B-3)); after the step (B-3), irradiating a predetermined region of the photoresist layer with radiation for development, thereby forming a resist pattern (step (B-4)); and after the step (B-4), etching the intermediate layer film with the resist pattern as a mask, etching the underlayer film with the obtained intermediate layer film pattern as an etching mask, and etching the substrate with the obtained underlayer film pattern as an etching mask, thereby forming a pattern on the substrate (step (B-5)).

The underlayer film for lithography of the present embodiment is not particularly limited by its formation method as long as it is formed from the composition for film formation for lithography of the present embodiment. A publicly known approach can be applied thereto. The underlayer film can be formed by, for example, applying the composition for film formation for lithography of the present embodiment onto a substrate by a publicly known coating method or printing method such as spin coating or screen printing, and then removing an organic solvent by volatilization or the like.

It is preferable to perform baking in the formation of the underlayer film, for preventing a mixing event with an upper layer resist while accelerating crosslinking reaction. In this case, the baking temperature is not particularly limited and is preferably in the range of 80 to 600° C., and more preferably 200 to 600° C. The baking time is not particularly limited and is preferably in the range of 10 to 300 seconds. The thickness of the underlayer film can be arbitrarily selected according to required performances and is not particularly limited, but is normally preferably 30 to 20,000 nm, more preferably 50 to 15,000 nm, and still more preferably 50 to 1000 nm.

After preparing the underlayer film on the substrate, in the case of a two-layer process, it is preferable to prepare a silicon-containing resist layer or a usual single-layer resist composed of hydrocarbon thereon, and in the case of a three-layer process, it is preferable to prepare a silicon-containing intermediate layer thereon and further prepare a single-layer resist layer not containing silicon thereon. In the case of a four-layer process, a silicon-containing intermediate layer is prepared on the underlayer film, an antireflection film is prepared thereon, and a single-layer resist layer not containing silicon is prepared thereon. In this case, for a photoresist material for forming this resist layer, a publicly known material can be used.

For the silicon-containing resist material for a two-layer process, a silicon atom-containing polymer such as a polysilsesquioxane derivative or a vinylsilane derivative is used as a base polymer, and a positive type photoresist material further containing an organic solvent, an acid generating agent, and if required, a basic compound or the like is preferably used, from the viewpoint of oxygen gas etching resistance. Here, a publicly known polymer that is used in this kind of resist material can be used as the silicon atom-containing polymer.

A polysilsesquioxane-based intermediate layer is preferably used as the silicon-containing intermediate layer for a three-layer process. By imparting effects as an antireflection film to the intermediate layer, there is a tendency that reflection can be effectively suppressed. For example, use of a material containing a large amount of an aromatic group and having high substrate etching resistance as the underlayer film in a process for exposure at 193 nm tends to increase a k value and enhance substrate reflection. However, the intermediate layer suppresses the reflection so that the substrate reflection can be 0.5% or less. The intermediate layer having such an antireflection effect is not limited, and polysilsesquioxane that crosslinks by an acid or heat in which a light absorbing group having a phenyl group or a silicon-silicon bond is introduced is preferably used for exposure at 193 nm.

Alternatively, an intermediate layer formed by chemical vapour deposition (CVD) may be used. As the intermediate layer formed by CVD, for example, a SiON film is known.

In general, the formation of an intermediate layer by a wet process such as spin coating or screen printing is more convenient and more advantageous in cost than CVD. The upper layer resist for a three-layer process may be positive type or negative type, and the same as a single-layer resist generally used can be used.

The underlayer film of the present embodiment can also be used as an antireflection film for usual single-layer resists or an underlying material for suppression of pattern collapse. The underlayer film of the present embodiment is excellent in etching resistance for an underlying process and can be expected to also function as a hard mask for an underlying process.

In the case of forming a resist layer from the above photoresist material, a wet process such as spin coating or screen printing is preferably used, as in the case of forming the above underlayer film. After coating with the resist material by spin coating or the like, prebaking is generally performed. This prebaking is preferably performed at 80 to 180° C. in the range of 10 to 300 seconds. Then, exposure, post-exposure baking (PEB), and development can be performed according to a conventional method to obtain a resist pattern. The thickness of the resist film is not particularly limited, and in general, is preferably 30 to 500 nm and more preferably 50 to 400 nm.

The exposure light can be arbitrarily selected and used according to the photoresist material to be used. General examples thereof can include a high energy ray having a wavelength of 300 nm or less, specifically, excimer laser of 248 nm, 193 nm, or 157 nm, soft x-ray of 3 to 20 nm, electron beam, and X-ray.

In a resist pattern formed by the method mentioned above, pattern collapse is suppressed by the underlayer film of the present embodiment. Therefore, use of the underlayer film of the present embodiment can produce a finer pattern and can reduce an exposure amount necessary for obtaining the resist pattern.

Next, etching is performed with the obtained resist pattern as a mask. Gas etching is preferably used as the etching of the underlayer film in a two-layer process. The gas etching is suitably etching using oxygen gas. In addition to oxygen gas, an inert gas such as He or Ar, or CO, CO₂, NH₃, SO₂, N₂, NO₂, or H₂ gas may be added. Alternatively, the gas etching may be performed with CO, CO₂, NH₃, N₂, NO₂, or H₂ gas without the use of oxygen gas. Particularly, the latter gas is preferably used from the viewpoint of side wall protection in order to prevent the undercut of pattern side walls.

On the other hand, gas etching is also preferably used as the etching of the intermediate layer in a three-layer process. The same gas etching as described in the two-layer process mentioned above is applicable. Particularly, it is preferable to process the intermediate layer in a three-layer process by using chlorofluorocarbon-based gas and using the resist pattern as a mask. Then, as mentioned above, for example, the underlayer film can be processed by oxygen gas etching with the intermediate layer pattern as a mask.

Here, in the case of forming an inorganic hard mask intermediate layer film as the intermediate layer, a silicon oxide film, a silicon nitride film, or a silicon oxynitride film (SiON film) is formed by CVD, ALD, or the like. A method for forming the nitride film is not limited, and for example, a method described in Japanese Patent Application Laid-Open No. 2002-334869 or International Publication No. WO 2004/066377 can be used. Although a photoresist film can be formed directly on such an intermediate layer film, an organic antireflection film (BARC) may be formed on the intermediate layer film by spin coating and a photoresist film may be formed thereon.

A polysilsesquioxane-based intermediate layer is preferably used as the intermediate layer. By imparting functions as an antireflection film to the resist intermediate layer film, there is a tendency that reflection can be effectively suppressed. A specific material for the polysilsesquioxane-based intermediate layer is not limited, and, for example, a material described in Japanese Patent Application Laid-Open No. 2007-226170 or Japanese Patent Application Laid-Open No. 2007-226204 can be used.

The subsequent etching of the substrate can also be performed by a conventional method. For example, the substrate made of SiO₂ or SiN can be etched mainly using chlorofluorocarbon-based gas, and the substrate made of p-Si, Al, or W can be etched mainly using chlorine- or bromine-based gas. In the case of etching the substrate with chlorofluorocarbon-based gas, the silicon-containing resist of the two-layer resist process or the silicon-containing intermediate layer of the three-layer process is stripped at the same time with substrate processing. On the other hand, in the case of etching the substrate with chlorine- or bromine-based gas, the silicon-containing resist layer or the silicon-containing intermediate layer is separately stripped and in general, stripped by dry etching using chlorofluorocarbon-based gas after substrate processing.

A feature of the underlayer film of the present embodiment is that it is excellent in etching resistance of these substrates. The substrate can be arbitrarily selected from publicly known ones and used and is not particularly limited. Examples thereof include Si, a-Si, p-Si, SiO₂, SiN, SiON, W, TiN, and Al. The substrate may be a laminate having a film to be processed (substrate to be processed) on a base material (support). Examples of such a film to be processed include various low-k films such as Si, SiO₂, SiON, SiN, p-Si, a-Si, W, W—Si, Al, Cu, and Al—Si, and stopper films thereof. A material different from that for the base material (support) is generally used. The thickness of the substrate to be processed or the film to be processed is not particularly limited, and normally, it is preferably approximately 50 to 1,000,000 nm and more preferably 75 to 500,000 nm.

### EXAMPLES

Hereinafter, the present invention will be described in further detail with reference to Examples and Comparative Examples, but the present invention is not limited by these examples in any way.

### [Molecular Weight]

The molecular weight of the synthesized resin was measured by GPC-MS analysis using Acquity UPLC/MALDI-Synapt HDMS manufactured by Waters Corporation.

### [Evaluation of Heat Resistance]

EXSTAR 6000 TG-DTA apparatus manufactured by SII NanoTechnology Inc. was used. About 5 mg of a sample was placed in an unsealed container made of aluminum, and the temperature was raised to 500° C. at a temperature increase rate of 10° C./min in a nitrogen gas stream (100 ml/min), thereby measuring the amount of thermogravimetric weight loss. From a practical viewpoint, evaluation A or B described below is preferable. When the evaluation is A or B, the sample has high heat resistance and is applicable to high temperature baking.

### <Evaluation Criteria>

A: The amount of thermogravimetric weight loss at 400° C. is less than 10%

B: The amount of thermogravimetric weight loss at 400° C. is 10% to 25%

C: The amount of thermogravimetric weight loss at 400° C. is greater than 25%

### [Evaluation of Solubility]

Cyclohexanone (CHN) as the solvent and the resin were added to a 50 ml screw bottle and stirred at 23° C. for 1 hour using a magnetic stirrer. Then, the amount of the compound and/or the resin dissolved in the solvent was measured and the result was evaluated according to the following criteria. From a practical viewpoint, evaluation A or B described below is preferable. When the evaluation is A or B, the sample has high storage stability in the solution state, and can be satisfyingly applied even in a fine processing process of semiconductors.

### <Evaluation Criteria>

A: 10% by mass or more

B: 5% by mass or more and less than 10% by mass

C: less than 5% by mass

### (Synthetic Example 1) Synthesis of BMI Citraconimide Resin

A container (internal capacity: 100 ml) equipped with a stirrer, a condenser tube, and a burette was prepared. To this container, 2.4 g of diaminodiphenylmethane oligomers obtained by following up on Synthetic Example 1 in Japanese Patent Application Laid-Open No. 2001-26571, 4.56 g (44.0 mmol) of citraconic anhydride (manufactured by KANTO CHEMICAL CO., INC.), 40 ml of dimethylformamide, and 60 ml of toluene were charged, and 0.4 g (2.3 mmol) of p-toluenesulfonic acid and 0.1 g of a polymerization inhibitor BHT were added, thereby preparing a reaction solution. The reaction solution was stirred at 110° C. for 8.0 hours to conduct reaction, and the produced water was recovered with a Dean-and-stark trap through azeotropic dehydration. Next, after cooling the reaction solution to 40° C., it was added dropwise into a beaker in which 300 ml of distilled water was placed to precipitate the product. After filtering the obtained slurry solution, the residue was washed with methanol to acquire 4.7 g of a citraconimide resin (BMI citraconimide resin) represented by the formula below. As a result of measuring the molecular weight of the obtained resin according to the above method, the weight average molecular weight was 446.

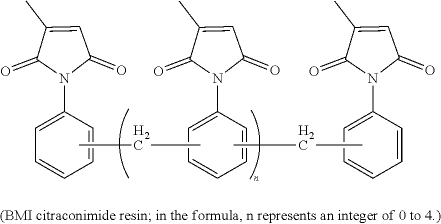

### (Synthetic Example 2) Synthesis of BAN Citraconimide Resin

A container (internal capacity: 100 ml) equipped with a stirrer, a condenser tube, and a burette was prepared. To this container, 6.30 g of a biphenyl aralkyl-based polyaniline resin (product name: BAN, manufactured by Nippon Kayaku Co., Ltd.), 4.56 g (44.0 mmol) of citraconic anhydride (manufactured by KANTO CHEMICAL CO., INC.), 40 ml of dimethylformamide, and 60 m1 of toluene were charged, and 0.4 g (2.3 mmol) of p-toluenesulfonic acid and 0.1 g of a polymerization inhibitor BHT were added, thereby preparing a reaction solution. The reaction solution was stirred at 110° C. for 6.0 hours to conduct reaction, and the produced water was recovered with a Dean-and-stark trap through azeotropic dehydration. Next, after cooling the reaction solution to 40° C., it was added dropwise into a beaker in which 300 m1 of distilled water was placed to precipitate the product. After filtering the obtained slurry solution, the residue was washed with methanol and subjected to separation and purification with column chromatography to acquire 5.5 g of the target compound (BAN citraconimide resin) represented by the formula below. As a result of measuring the molecular weight of the obtained resin according to the above method, the weight average molecular weight was 832.

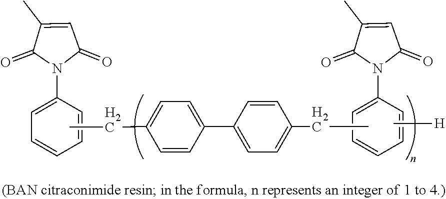

### <Example 1> Monomer-Removed BMI-2300

To a 300 mL flask, 20 g of a phenylmethane maleimide resin (product name: BMI-2300, manufactured by Daiwa Kasei Industry Co., Ltd.) and 60 g of methyl ethyl ketone were charged, and by heating the resultant mixture to 60° C. for dissolution, a solution was obtained. The above solution was adsorbed on a neutral silica gel (manufactured by Kanto Chemical Co., Inc.), and by using silica gel column chromatography and developing a mixed solvent of ethyl acetate (20% by weight)/hexane (80% by weight), only the component of the repeating unit represented by the following formula was separated. After concentration, vacuum drying was performed to remove the solvent, thereby obtaining a film forming material for lithography.

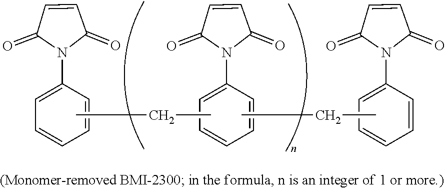

As a result of measuring the average molecular weight of the separated maleimide resin, it was 680.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the composition shown in Table 1.

### <Example 1A> High Molecular Weight BMI-2300 Polymer

In the same manner as in Example 1, only the component of the repeating unit represented by the following formula was separated from the phenylmethane maleimide resin, and after concentration, vacuum drying was performed to remove the solvent, thereby obtaining a film forming material for lithography.

As a result of measuring the average molecular weight of the separated maleimide resin, it was 760.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared in the same manner as in the above Example 1.

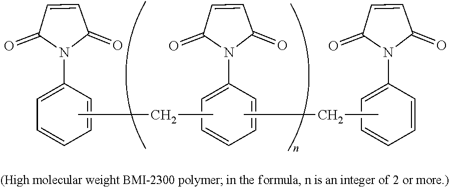

### <Example 2> Monomer-Removed MIR-3000-L

To a 300 mL flask, 20 g of a biphenyl aralkyl-based maleimide resin (product name: MIR-3000-L, manufactured by Nippon Kayaku Co., Ltd.) and 60 g of methyl ethyl ketone were charged, and by heating the resultant mixture to 60° C. for dissolution, a solution was obtained. The above solution was adsorbed on a neutral silica gel (manufactured by Kanto Chemical Co., Inc.), and by using silica gel column chromatography and developing a mixed solvent of ethyl acetate (20% by weight)/hexane (80% by weight), only the component of the repeating unit represented by the following formula was separated. After concentration, vacuum drying was performed to remove the solvent, thereby obtaining a film forming material for lithography.

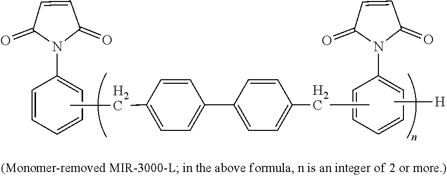

As a result of measuring the average molecular weight of the separated maleimide resin, it was 1142.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared in the same manner as in the above Example 1.

### <Example 2A> High Molecular Weight MIR-3000-L Polymer

In the same manner as in Example 1, only the component of the repeating unit represented by the following formula was separated from the biphenyl aralkyl-based maleimide resin, and after concentration, vacuum drying was performed to remove the solvent, thereby obtaining a film forming material for lithography.

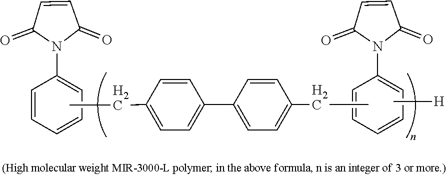

As a result of measuring the average molecular weight of the separated maleimide resin, it was 1322.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared in the same manner as in the above Example 1.

### Example 3

10 parts by mass of the phenylmethane maleimide resin obtained in Example 1 (monomer-removed BMI-2300) and 0.5 parts by mass of 2,4,5-triphenylimidazole (TPIZ) as a crosslinking promoting agent were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more and less than 20% by mass (evaluation A), and the obtained film forming material for lithography was evaluated to have excellent solubility. Thus, a composition for film formation for lithography was prepared according to the same operations as in the above Example 1.

### Example 3A

10 parts by mass of the phenylmethane maleimide resin obtained in Example 1A (high molecular weight BMI-2300 polymer) and 0.5 parts by mass of 2,4,5-triphenylimidazole (TPIZ) as a crosslinking promoting agent were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more and less than 20% by mass (evaluation A), and the obtained film forming material for lithography was evaluated to have excellent solubility. Thus, a composition for film formation for lithography was prepared according to the same operations as in the above Example 1.

### Example 4

10 parts by mass of the biphenyl aralkyl-based maleimide resin obtained in Example 2 (monomer-removed MIR-3000-L) and 0.5 parts by mass of 2,4,5-triphenylimidazole (TPIZ) as a crosslinking promoting agent were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more and less than 20% by mass (evaluation A), and the obtained film forming material for lithography was evaluated to have excellent solubility. Thus, a composition for film formation for lithography was prepared according to the same operations as in the above Example 1.

### Example 4A

10 parts by mass of the biphenyl aralkyl-based maleimide resin obtained in Example 2A (high molecular weight MIR-3000-L polymer) and 0.5 parts by mass of 2,4,5-triphenylimidazole (TPIZ) as a crosslinking promoting agent were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more and less than 20% by mass (evaluation A), and the obtained film forming material for lithography was evaluated to have excellent solubility. Thus, a composition for film formation for lithography was prepared according to the same operations as in the above Example 1.

### Example 5

As the maleimide resin, 10 parts by mass of the monomer-removed BMI-2300 obtained in Example 1 was used. In addition, 2 parts by mass of benzoxazine (product name: BF-BXZ, manufactured by KONISHI CHEMICAL IND. CO., LTD.) represented by the following formula was used as the crosslinking agent and 0.5 parts by mass of 2,4,5-triphenylimidazole (TPIZ) was compounded as the crosslinking promoting agent to prepare a film forming material for lithography.

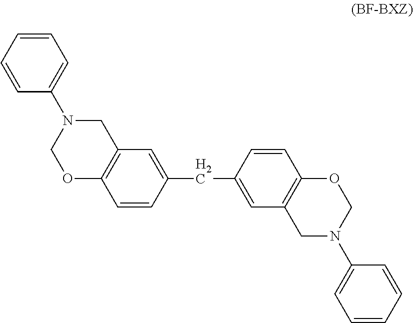 [SMILES: c1ccc(N2COc3ccc(Cc4ccc5c(c4)CN(c4ccccc4)CO5)cc3C2)cc1]

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the same operations as in the above Example 1.

### Example 5A

As the maleimide resin, 10 parts by mass of the high molecular weight BMI-2300 polymer, obtained in Example 1A, was used. In addition, 2 parts by mass of the benzoxazine described above (product name: BF-BXZ, manufactured by KONISHI CHEMICAL IND. CO., LTD.) was used as the crosslinking agent and 0.5 parts by mass of 2,4,5-triphenylimidazole (TPIZ) was compounded as the crosslinking promoting agent to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the same operations as in the above Example 1.

### Example 6

As the maleimide resin, 10 parts by mass of the monomer-removed BMI-2300 obtained in Example 1 was used. In addition, 2 parts by mass of a biphenyl aralkyl-based epoxy resin (product name: NC-3000-L, manufactured by Nippon Kayaku Co., Ltd.) represented by the following formula was used as the crosslinking agent and 0.5 parts by mass of TPIZ was compounded as the crosslinking promoting agent to prepare a film forming material for lithography.

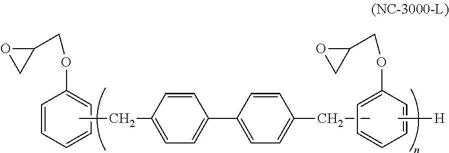

(In the above formula, n is an integer of 1 to 4.)

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the same operations as in the above Example 1.

### Example 6A

As the maleimide resin, 10 parts by mass of the high molecular weight BMI-2300 polymer, obtained in Example 1, was used. In addition, 2 parts by mass of the biphenyl aralkyl-based epoxy resin described above (product name: NC-3000-L, manufactured by Nippon Kayaku Co., Ltd.) was used as the crosslinking agent and 0.5 parts by mass of TPIZ was compounded as the crosslinking promoting agent to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the same operations as in the above Example 1.

### Example 7

As the maleimide resin, 10 parts by mass of the monomer-removed BMI-2300 obtained in Example 1 was used. In addition, 2 parts by mass of a diallylbisphenol A-based cyanate (product name: DABPA-CN, manufactured by MITSUBISHI GAS CHEMICAL COMPANY, INC.) represented by the following formula was used as the crosslinking agent and 0.5 parts by mass of 2,4,5-triphenylimidazole (TPIZ) was compounded as the crosslinking promoting agent to prepare a film forming material for lithography.

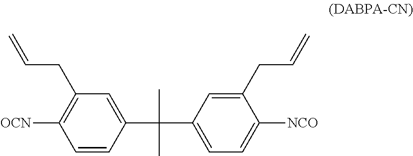

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the same operations as in the above Example 1.

### Example 7A

As the maleimide resin, 10 parts by mass of the high molecular weight BMI-2300 polymer, obtained in Example 1A, was used. In addition, 2 parts by mass of the diallylbisphenol A-based cyanate described above (product name: DABPA-CN, manufactured by MITSUBISHI GAS CHEMICAL COMPANY, INC.) was used as the crosslinking agent and 0.5 parts by mass of 2,4,5-triphenylimidazole (TPIZ) was compounded as the crosslinking promoting agent to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the same operations as in the above Example 1.

### Example 8

As the maleimide resin, 10 parts by mass of the monomer-removed BMI-2300 obtained in Example 1 was used. In addition, 2 parts by mass of diallylbisphenol A (product name: BPA-CA, manufactured by KONISHI CHEMICAL IND. CO., LTD.) represented by the following formula was used as the crosslinking agent and 0.5 parts by mass of 2,4,5-triphenylimidazole (TPIZ) was compounded as the crosslinking promoting agent to prepare a film forming material for lithography.

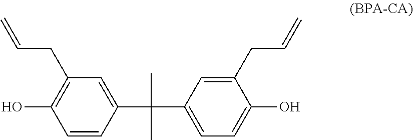 [SMILES: C=CCc1cc(C(C)(C)c2ccc(O)c(CC=C)c2)ccc1O]

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the same operations as in the above Example 1.

### Example 8A

As the maleimide resin, 10 parts by mass of the high molecular weight BMI-2300 polymer, obtained in Example 1A, was used. In addition, 2 parts by mass of the diallylbisphenol A described above (product name: BPA-CA, manufactured by KONISHI CHEMICAL IND. CO., LTD.) was used as the crosslinking agent and 0.5 parts by mass of 2,4,5-triphenylimidazole (TPIZ) was compounded as the crosslinking promoting agent to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the same operations as in the above Example 1.

### Example 9

As the maleimide resin, 10 parts by mass of the monomer-removed BMI-2300 obtained in Example 1 was used. In addition, 2 parts by mass of a diphenylmethane-based allylphenolic resin (product name: APG-1, manufactured by Gun Ei Chemical Industry Co., Ltd.) represented by the following formula was used as the crosslinking agent to prepare a film forming material for lithography.

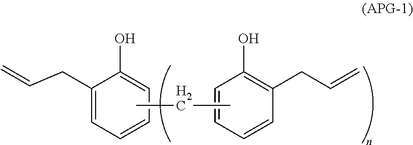

(In the above formula, n is an integer of 1 to 3.)

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the same operations as in the above Example 1.

### Example 9A

As the maleimide resin, 10 parts by mass of the high molecular weight BMI-2300 polymer, obtained in Example 1A, was used. In addition, 2 parts by mass of the diphenylmethane-based allylphenolic resin described above (product name: APG-1, manufactured by Gun Ei Chemical Industry Co., Ltd.) was used as the crosslinking agent to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the same operations as in the above Example 1.

### Example 10

As the maleimide resin, 10 parts by mass of the monomer-removed BMI-2300 obtained in Example 1 was used. In addition, 2 parts by mass of a diphenylmethane-based propenylphenolic resin (product name: APG-2, manufactured by Gun Ei Chemical Industry Co., Ltd.) represented by the following formula was used as the crosslinking agent to prepare a film forming material for lithography.

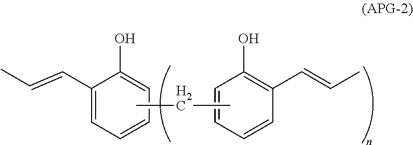

(In the above formula, n is an integer of 1 to 3.)

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 10A

As the maleimide resin, 10 parts by mass of the high molecular weight BMI-2300 polymer, obtained in Example 1A, was used. In addition, 2 parts by mass of the diphenylmethane-based propenylphenolic resin described above (product name: APG-2, manufactured by Gun Ei Chemical Industry Co., Ltd.) was used as the crosslinking agent to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 11

By using 10 parts by mass of the monomer-removed BMI-2300 obtained in Example 1 as the maleimide resin and also 2 parts by mass of 4,4′-diaminodiphenylmethane (product name DDM, manufactured by Tokyo Chemical Industry Co., Ltd.) represented by the following formula as the crosslinking agent, a film forming material for lithography was prepared.

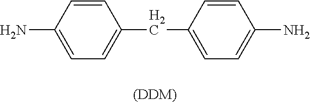

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 11A

By using 10 parts by mass of the high molecular weight BMI-2300 polymer, obtained in Example 1A, as the maleimide resin and also 2 parts by mass of the 4,4′-diaminodiphenylmethane described above (product name DDM, manufactured by Tokyo Chemical Industry Co., Ltd.) as the crosslinking agent, a film forming material for lithography was prepared.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### <Example 12> Monomer-Removed BMI Citraconimide

To a 300 mL flask, 20 g of the BMI citraconimide resin obtained in Synthetic Example 1 as the maleimide resin and 60 g of methyl ethyl ketone were charged, and by heating the resultant mixture to 60° C. for dissolution, a solution was obtained. The above solution was adsorbed on a neutral silica gel (manufactured by Kanto Chemical Co., Inc.), and by using silica gel column chromatography and developing a mixed solvent of ethyl acetate (20% by weight)/hexane (80% by weight), only the component of the repeating unit represented by the following formula was separated. After concentration, vacuum drying was performed to remove the solvent, thereby obtaining a film forming material for lithography.

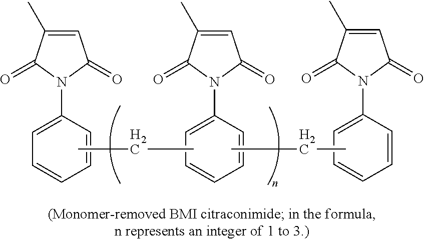

As a result of measuring the average molecular weight of the separated citraconimide resin, it was 836.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the composition shown in Table 1.

### <Example 12A> High Molecular Weight BMI Citraconimide Polymer

In the same manner as in Example 12, only the component of the repeating unit represented by the following formula was separated from the BMI citraconimide resin obtained in Synthetic Example 1, and after concentration, vacuum drying was performed to remove the solvent, thereby obtaining a film forming material for lithography.

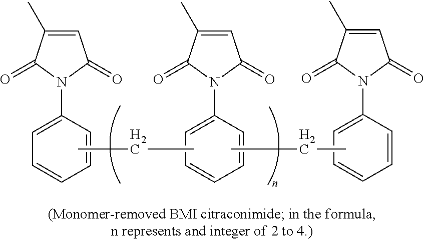

As a result of measuring the average molecular weight of the separated citraconimide resin, it was 936.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the composition shown in Table 1.

### <Example 13> Monomer-Removed BAN Citraconimide

To a 300 mL flask, 20 g of the BAN citraconimide resin obtained in Synthetic Example 2 as the maleimide resin and 60 g of methyl ethyl ketone were charged, and by heating the resultant mixture to 60° C. for dissolution, a solution was obtained. The above solution was adsorbed on a neutral silica gel (manufactured by Kanto Chemical Co., Inc.), and by using silica gel column chromatography and developing a mixed solvent of ethyl acetate (20% by weight)/hexane (80% by weight), only the component of the repeating unit represented by the following formula was separated. After concentration, vacuum drying was performed to remove the solvent, thereby obtaining a film forming material for lithography.

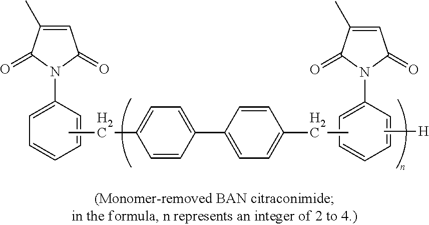

As a result of measuring the average molecular weight of the separated, monomer-removed citraconimide, it was 1168.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the composition shown in Table 1.

### <Example 13A> High Molecular Weight BAN Citraconimide Polymer

In the same manner as in Example 13, only the component of the repeating unit represented by the following formula was separated from the BAN citraconimide resin obtained in Synthetic Example 2, and after concentration, vacuum drying was performed to remove the solvent, thereby obtaining a film forming material for lithography.

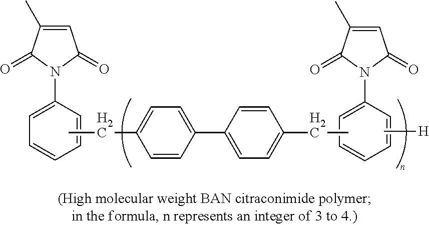

As a result of measuring the average molecular weight of the separated, high molecular weight citraconimide polymer, it was 1278.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the composition shown in Table 1.

### Example 14

10 parts by mass of the monomer-removed BMI citraconimide obtained in Example 12 and 0.5 parts by mass of 2,4,5-triphenylimidazole (TPIZ) as a crosslinking promoting agent were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more and less than 20% by mass (evaluation A), and the obtained film forming material for lithography was evaluated to have excellent solubility. Thus, a composition for film formation for lithography was prepared according to the same operations as in the above Example 1.

### Example 14A

10 parts by mass of the high molecular weight BMI citraconimide polymer, obtained in Example 12A, and 0.5 parts by mass of 2,4,5-triphenylimidazole (TPIZ) as a crosslinking promoting agent were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more and less than 20% by mass (evaluation A), and the obtained film forming material for lithography was evaluated to have excellent solubility. Thus, a composition for film formation for lithography was prepared according to the same operations as in the above Example 1.

### Example 15

10 parts by mass of the monomer-removed BAN citraconimide obtained in Example 13 and 0.5 parts by mass of 2,4,5-triphenylimidazole (TPIZ) as a crosslinking promoting agent were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more and less than 20% by mass (evaluation A), and the obtained film forming material for lithography was evaluated to have excellent solubility. Thus, a composition for film formation for lithography was prepared according to the same operations as in the above Example 1.

### Example 15A

10 parts by mass of the high molecular weight BAN citraconimide polymer, obtained in Example 13A, and 0.5 parts by mass of 2,4,5-triphenylimidazole (TPIZ) as a crosslinking promoting agent were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more and less than 20% by mass (evaluation A), and the obtained film forming material for lithography was evaluated to have excellent solubility. Thus, a composition for film formation for lithography was prepared according to the same operations as in the above Example 1.

### Comparative Example 1

10 parts by mass of N,N′-biphenyl-based bismaleimide BMI (product name: BMI monomer, manufactured by Daiwa Kasei Industry Co., Ltd.) represented by the following formula as the maleimide compound and 0.1 parts by mass of 2,4,5-triphenylimidazole (TPIZ) as a crosslinking promoting agent were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

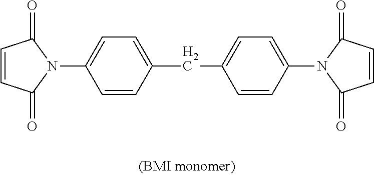 [SMILES: O=C1C=CC(=O)N1c1ccc(Cc2ccc(N3C(=O)C=CC3=O)cc2)cc1]

### Comparative Example 2

To a 300 mL flask, 20 g of a biphenyl aralkyl-based maleimide resin (product name: MIR-3000-L, manufactured by Nippon Kayaku Co., Ltd.) represented by the following formula as the maleimide compound and 60 g of methyl ethyl ketone were charged, and by heating the resultant mixture to 60° C. for dissolution, a solution was obtained. The above solution was adsorbed on a neutral silica gel (manufactured by Kanto Chemical Co., Inc.), and by using silica gel column chromatography and developing a mixed solvent of ethyl acetate/hexane, only the component represented by the following formula was separated. After concentration, vacuum drying was performed to remove the solvent, thereby obtaining the target compound.

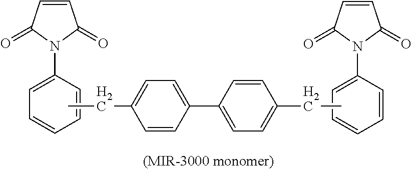

As a result of measuring the molecular weight of the separated maleimide compound, it was 556.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared in the same manner as in the above Example 1.

### Comparative Example 3

To a 300 mL flask, 20 g of the BMI citraconimide resin obtained in Synthetic Example 1 as the maleimide compound and 60 g of methyl ethyl ketone were charged, and by heating the resultant mixture to 60° C. for dissolution, a solution was obtained. The above solution was adsorbed on a neutral silica gel (manufactured by Kanto Chemical Co., Inc.), and by using silica gel column chromatography and developing a mixed solvent of ethyl acetate/hexane, only the component represented by the following formula was separated. After concentration, vacuum drying was performed to remove the solvent, thereby obtaining the target compound.

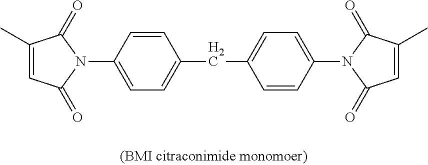

As a result of measuring the molecular weight of the separated maleimide compound, it was 386.

As a result of thermogravimetry, the amount of thermogravimetric weight loss at 400° C. of the obtained film forming material for lithography was 20% or more (evaluation C). In addition, as a result of evaluation of solubility in CHN, the solubility was 10% by mass or more (evaluation A), and the obtained film forming material for lithography was evaluated to have excellent solubility. Thus, a composition for film formation for lithography was prepared in the same manner as in the above Example 1.

### Comparative Example 4

To a 300 mL flask, 20 g of the BAN citraconimide resin obtained in Synthetic Example 2 as the maleimide compound and 60 g of methyl ethyl ketone were charged, and by heating the resultant mixture to 60° C. for dissolution, a solution was obtained. The above solution was adsorbed on a neutral silica gel (manufactured by Kanto Chemical Co., Inc.), and by using silica gel column chromatography and developing a mixed solvent of ethyl acetate/hexane, only the component represented by the following formula was separated. After concentration, vacuum drying was performed to remove the solvent, thereby obtaining the target compound.

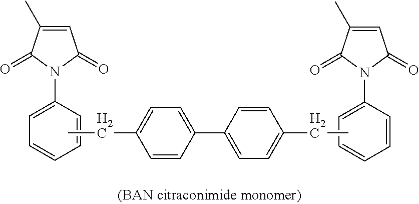

As a result of measuring the molecular weight of the separated maleimide compound, it was 584.

As a result of thermogravimetry, the amount of thermogravimetric weight loss at 400° C. of the obtained film forming material for lithography was 20% or more (evaluation C). In addition, as a result of evaluation of solubility in CHN, the solubility was 10% by mass or more (evaluation A), and the obtained film forming material for lithography was evaluated to have excellent solubility. Thus, a composition for film formation for lithography was prepared in the same manner as in the above Example 1.

### Example 16

As the maleimide resin, 10 parts by mass of the monomer-removed BMI-2300 obtained in Example 1 was used. In addition, 0.2 parts by mass of IRGACURE 184 (manufactured by BASF SE) represented by the following formula was compounded as the photo-radical polymerization initiator to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

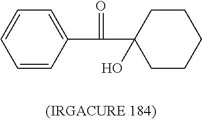 [SMILES: O=C(c1ccccc1)C1(O)CCCCC1]

### Example 16A

As the maleimide resin, 10 parts by mass of the high molecular weight BMI-2300 polymer, obtained in Example 1, was used. In addition, 0.2 parts by mass of IRGACURE 184 (manufactured by BASF SE) was compounded as the photo-radical polymerization initiator to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 17

As the maleimide resin, 10 parts by mass of the monomer-removed MIR-3000-L obtained in Example 2 was used. In addition, 0.1 parts by mass of IRGACURE 184 (manufactured by BASF SE) was compounded as the photo-radical polymerization initiator to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 17A

As the maleimide resin, 10 parts by mass of the high molecular weight MIR-3000-L polymer, obtained in Example 2A, was used. In addition, 0.1 parts by mass of IRGACURE 184 (manufactured by BASF SE) was compounded as the photo-radical polymerization initiator, thereby preparing a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 18

A composition for film formation for lithography was prepared with the same composition as in Example 16, except that 10 parts by mass of the monomer-removed BMI citraconimide obtained in Example 12 was used as the maleimide resin. As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 18A

A composition for film formation for lithography was prepared with the same composition as in Example 16, except that 10 parts by mass of the high molecular weight BMI citraconimide polymer, obtained in Example 12A, was used as the maleimide resin. As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 19

A composition for film formation for lithography was prepared with the same composition as in Example 16, except that 10 parts by mass of the monomer-removed BAN citraconimide obtained in Example 13 was used as the maleimide resin. As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 19A

A composition for film formation for lithography was prepared with the same composition as in Example 16, except that 10 parts by mass of the high molecular weight BAN citraconimide polymer, obtained in Example 13A, was used as the maleimide resin. As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 20

As the maleimide resin, 10 parts by mass of the monomer-removed BMI-2300 obtained in Example 1 was used. In addition, 0.2 parts by mass of WPBG-300 (manufactured by FUJIFILM Wako Pure Chemical Corporation) represented by the following formula was compounded as the photobase generating agent to prepare a film forming material for lithography. As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

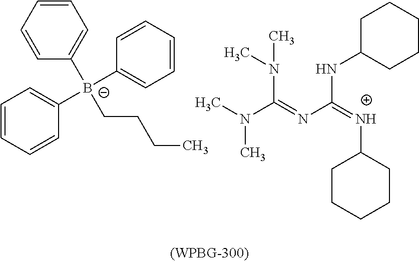 [SMILES: CCCC[B-](c1ccccc1)(c1ccccc1)c1ccccc1 ; CN(C)C(=N/C(NC1CCCCC1)=[NH+]\C1CCCCC1)N(C)C]

### Example 20A

As the maleimide resin, 10 parts by mass of the high molecular weight BMI-2300 polymer, obtained in Example 1A, was used. In addition, 0.2 parts by mass of WPBG-300 was compounded as the photobase generating agent to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 21

As the maleimide resin, 10 parts by mass of the monomer-removed MIR-3000-L obtained in Example 2 was used. In addition, 0.2 parts by mass of WPBG-300 was compounded as the photobase generating agent to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 21A

As the maleimide resin, 10 parts by mass of the high molecular weight MIR-3000-L polymer, obtained in Example 2A, was used. In addition, 0.2 parts by mass of WPBG-300 was compounded as the photobase generating agent to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 22

A composition for film formation for lithography was prepared with the same composition as in Example 20, except that 10 parts by mass of the monomer-removed BMI citraconimide obtained in Example 12 was used as the maleimide resin. As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 22A

A composition for film formation for lithography was prepared with the same composition as in Example 20, except that 10 parts by mass of the high molecular weight BMI citraconimide polymer, obtained in Example 12A, was used as the maleimide resin. As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 23

A composition for film formation for lithography was prepared with the same composition as in Example 20, except that 10 parts by mass of the monomer-removed BAN citraconimide obtained in Example 13 was used as the maleimide resin. As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A) and the obtained film forming material for lithography was evaluated to have excellent solubility. Thus, a composition for film formation for lithography was prepared according to the same operations as in the above Example 1.

### Example 23A

A composition for film formation for lithography was prepared with the same composition as in Example 20, except that 10 parts by mass of the high molecular weight BAN citraconimide polymer, obtained in Example 13A, was used as the maleimide resin. As a result of thermogravimetry, the amount of thermogravimetric weight loss at 400° C. of the obtained film forming material for lithography was less than 10% (evaluation A). In addition, as a result of evaluation of solubility in CHN, the solubility was 10% by mass or more (evaluation A), and the obtained film forming material for lithography was evaluated to have excellent solubility. Thus, a composition for film formation for lithography was prepared according to the same operations as in the above Example 1.

### [Evaluation]

A silicon substrate was spin coated with each of these compositions for film formation for lithography of Examples 1 to 15, 1A to 15A, and Comparative Examples 1 to 4, and then prebaked at 150° C. for 60 seconds. Then, the film thickness was measured and defined as the initial film thickness. Thereafter, the substrate was subjected to curing baking at 240° C. for 60 seconds, and the film thickness of the coated film was measured. From the difference in film thickness between the initial film thickness and that after the curing baking, the decreasing rate of film thickness (%) was calculated to evaluate the sublimation resistance of each underlayer film under the conditions shown below.

Thereafter, the silicon substrate was immersed in a mixed solvent of 70% PGMEA/30% PGME for 60 seconds, the adhered solvent was removed with an Aero Duster, and then the substrate was subjected to solvent drying at 110° C. From the difference in film thickness before and after the immersion, the decreasing rate of film thickness (%) was calculated to evaluate the curability of each underlayer film under the conditions shown below.

The underlayer films after the curing baking at 240° C. were further subjected to postbaking at 450° C. for 240 seconds under a nitrogen purged environment, and from the difference in film thickness before and after the baking, the decreasing rate of film thickness (%) was calculated to evaluate the film heat resistance of each underlayer film. In addition, the embedding properties to a substrate having difference in level and the flatness were evaluated under the conditions shown below.

A silicon substrate was spin coated with each of these compositions for film formation for lithography of Examples 16 to 23 and 16A to 23A, and then baked at 150° C. for 60 seconds to remove the solvent in the coated film. Subsequently, the film was cured using a high pressure mercury lamp with an accumulated light exposure of 1500 mJ/cm² and an irradiation time of 60 seconds, and then the film thickness of the coated film was measured. Thereafter, the silicon substrate was immersed in a mixed solvent of 70% PGMEA/30% PGME for 60 seconds, the adhered solvent was removed with an Aero Duster, and the substrate was then subjected to solvent drying at 110° C. From the difference in film thickness before and after the immersion, the decreasing rate of film thickness (%) was calculated to evaluate the curability of each underlayer film under the conditions shown below.

The underlayer films were further baked at 450° C. for 240 seconds, and from the difference in film thickness before and after the baking, the decreasing rate of film thickness (%) was calculated to evaluate the film heat resistance of each underlayer film. In addition, the embedding properties to a substrate having difference in level and the flatness were evaluated under the conditions shown below.

### [Evaluation of Curability]

### <Evaluation Criteria>

S: Decreasing rate of film thickness before and after solvent immersion ≤1%

A: Decreasing rate of film thickness before and after solvent immersion ≤5%

B: Decreasing rate of film thickness before and after solvent immersion ≤10%

C: Decreasing rate of film thickness before and after solvent immersion >10%

### [Evaluation of Film Heat Resistance]

### <Evaluation Criteria>

S: Decreasing rate of film thickness before and after baking at 450° C.≤10%

A: Decreasing rate of film thickness before and after baking at 450° C. 15%

B: Decreasing rate of film thickness before and after baking at 450° C.≤20%

C: Decreasing rate of film thickness before and after baking at 450° C. >20%

[Evaluation of embedding properties to substrate having difference in level]

The embedding properties to a substrate having difference in level were evaluated by the following procedures.

A SiO₂ substrate having a film thickness of 80 nm and a line and space pattern of 60 nm was coated with a composition for underlayer film formation for lithography, and baked at 240° C. for 60 seconds to form a 90 nm underlayer film. The cross section of the obtained film was cut out and observed under an electron microscope to evaluate the embedding properties to a substrate having difference in level.

### <Evaluation Criteria>

◯: The underlayer film was embedded without defects in the asperities of the SiO₂ substrate having a line and space pattern of 60 nm.

X: The asperities of the SiO₂ substrate having a line and space pattern of 60 nm had defects which hindered the embedding of the underlayer film.

### [Evaluation of Flatness]

Onto a SiO₂ substrate having difference in level on which trenches with a width of 100 nm, a pitch of 150 nm, and a depth of 150 nm (aspect ratio: 1.5) and trenches with a width of 5 μm and a depth of 180 nm (open space) were mixedly present, each of the obtained compositions for film formation was coated. Subsequently, it was calcined at 240° C. for 120 seconds under the air atmosphere to form a resist underlayer film having a film thickness of 200 nm. The shape of this resist underlayer film was observed with a scanning electron microscope (“S—4800” from Hitachi High-Technologies Corporation), and the difference between the maximum value and the minimum value of the film thickness of the resist underlayer film on the trench or space (AFT) was measured.

### <Evaluation Criteria>

SS: ΔFT<5 nm (best flatness)
S: 5 nm≤ΔFT<10 nm (excellent flatness)
A: 10 nm≤ΔFT<20 nm (good flatness)
B: 20 nm≤ΔFT<40 nm (partially good flatness)
C: 40 nm≤ΔFT (poor flatness)

TABLE 1

| | | | | Crosslinking | | | | | |
|---|---|---|---|---|---|---|---|---|---|
| | | Crosslinking | | promoting | | | Film heat | Embedding | |
| | Maleimide resin | agent | | agent | Solvent | Curability | resistance | properties | Flatness |
| Ex. 1 | Monomer-removed BMI-2300 (10) | — | | — | CHN (90) | S | S | ◯ | A |
| Ex. 1A | High molecular weight BMI-2300 | — | | — | CHN (90) | S | S | ◯ | S |
| | polymer (10) | | | | | | | | |
| Ex. 2 | Monomer-removed MIR-3000-L (10) | — | | — | CHN (90) | S | S | ◯ | A |
| Ex. 2A | Monomer-removed MIR-3000-L (10) | — | | — | CHN (90) | S | S | ◯ | S |
| Ex. 3 | Monomer-removed BMI-2300 (10) | — | | TPIZ (0.5) | CHN (90) | S | S | ◯ | A |
| Ex. 3A | High molecular weight BMI-2300 | — | | TPIZ (0.5) | CHN (90) | S | S | ◯ | S |
| | polymer (10) | | | | | | | | |
| Ex. 4 | Monomer-removed MIR-3000-L (10) | — | | TPIZ (0.5) | CHN (90) | S | S | ◯ | A |
| Ex. 4A | Monomer-removed MIR-3000-L (10) | | | TPIZ (0.5) | CHN (90) | S | S | ◯ | S |
| Ex. 5 | Monomer-removed BMI-2300 (10) | BF-BXZ | (2) | TPIZ (0.5) | CHN (90) | A | A | ◯ | B |
| Ex. 5A | High molecular weight BMI-2300 | BF-BXZ | (2) | TPIZ (0.5) | CHN (90) | A | A | ◯ | A |
| | polymer (10) | | | | | | | | |
| Ex. 6 | Monomer-removed BMI-2300 (10) | NC-3000-L | (2) | TPIZ (0.5) | CHN (90) | A | A | ◯ | B |
| Ex. 6A | High molecular weight BMI-2300 | NC-3000-L | (2) | TPIZ (0.5) | CHN (90) | A | A | ◯ | A |
| | polymer (10) | | | | | | | | |
| Ex. 7 | Monomer-removed BMI-2300 (10) | DABPA-CN | (2) | TPIZ (0.5) | CHN (90) | A | A | ◯ | B |
| Ex. 7A | High molecular weight BMI-2300 | DABPA-CN | (2) | TPIZ (0.5) | CHN (90) | A | A | ◯ | A |
| | polymer (10) | | | | | | | | |
| Ex. 8 | Monomer-removed BMI-2300 (10) | BPA-CA | (2) | TPIZ (0.5) | CHN (90) | A | A | ◯ | B |
| Ex. 8A | High molecular weight BMI-2300 | BPA-CA | (2) | TPIZ (0.5) | CHN (90) | A | A | ◯ | A |
| | polymer (10) | | | | | | | | |
| Ex. 9 | Monomer-removed BMI-2300 (10) | APG-1 | (2) | TPIZ (0.5) | CHN (90) | S | S | ◯ | B |
| Ex. 9A | High molecular weight BMI-2300 | APG-1 | (2) | TPIZ (0.5) | CHN (90) | S | S | ◯ | A |
| | polymer (10) | | | | | | | | |
| Ex. 10 | Monomer-removed BMI-2300 (10) | APG-2 | (2) | TPIZ (0.5) | CHN (90) | S | S | ◯ | B |
| Ex. 10A | High molecular weight BMI-2300 | APG-2 | (2) | TPIZ (0.5) | CHN (90) | S | S | ◯ | A |
| | polymer (10) | | | | | | | | |
| Ex. 11 | Monomer-removed BMI-2300 (10) | DDM | (2) | TPIZ (0.5) | CHN (90) | S | A | ◯ | B |
| Ex. 11A | High molecular weight BMI-2300 | DDM | (2) | TPIZ (0.5) | CHN (90) | S | A | ◯ | A |
| | polymer (10) | | | | | | | | |

| | | | | | | | | |
|---|---|---|---|---|---|---|---|---|
| Ex. 12 | Monomer-removed BMI citraconimide | — | — | CHN (90) | A | A | ◯ | S |
| | (10) | | | | | | | |
| Ex. 12A | High molecular weight BMI | — | — | CHN (90) | A | A | ◯ | SS |
| | citraconimide polymer (10) | | | | | | | |
| Ex. 13 | Monomer-removed BAN citraconimide | — | — | CHN (90) | A | A | ◯ | S |
| | (10) | | | | | | | |
| Ex. 13A | High molecular weight BAN | — | — | CHN (90) | A | A | ◯ | SS |
| | citraconimide polymer (10) | | | | | | | |
| Ex. 14 | Monomer-removed BMI citraconimide | — | TPIZ (0.5) | CHN (90) | A | A | ◯ | S |
| | (10) | | | | | | | |
| Ex. 14A | High molecular weight BMI | — | TPIZ (0.5) | CHN (90) | A | A | ◯ | SS |
| | citraconimide polymer (10) | | | | | | | |
| Ex. 15 | Monomer-removed BAN citraconimide | — | TPIZ (0.5) | CHN (90) | A | A | ◯ | S |
| | (10) | | | | | | | |
| Ex. 15A | High molecular weight BAN | | TPIZ (0.5) | CHN (90) | A | A | ◯ | SS |
| | citraconimide polymer (10) | | | | | | | |
| Comp. | BMI monomer (10) | — | — | CHN (90) | B | B | ◯ | S |
| Ex. 1 | | | | | | | | |
| Comp. | MIR-3000-L monomer (10) | — | — | CHN (90) | B | B | ◯ | S |
| Ex. 2 | | | | | | | | |
| Comp. | BMI citraconimide monomer (10) | — | TPIZ (0.5) | CHN (90) | B | B | ◯ | S |
| Ex. 3 | | | | | | | | |
| Comp. | BAN citraconimide monomer (10) | — | TPIZ (0.5) | CHN (90) | B | B | ◯ | S |
| Ex. 4 | | | | | | | | |

*The value shown in the parentheses represent parts by mass of each component.

TABLE 2

| | | | Crosslinking | | | | | | |
|---|---|---|---|---|---|---|---|---|---|
| | | Crosslinking | promoting | | | | Film heat | Embedding | |
| | Maleimide resin | agent | agent | | Solvent | Curability | resistance | properties | Flatness |
| Example | Monomer-removed BMI- | — | IRGACURE-184 | (0.5) | CHN (90) | S | S | ◯ | S |
| 16 | 2300 (10) | | | | | | | | |
| Example | High molecular weight | — | IRGACURE-184 | (0.5) | CHN (90) | S | S | ◯ | SS |
| 16A | BMI-2300 polymer (10) | | | | | | | | |
| Example | Monomer-removed MIR- | — | IRGACURE-184 | (0.5) | CHN (90) | S | S | ◯ | S |
| 17 | 3000-L (10) | | | | | | | | |
| Example | High molecular weight | — | IRGACURE-184 | (0.5) | CHN (90) | S | S | ◯ | SS |
| 17A | MIR-3000-L polymer (10) | | | | | | | | |
| Example | Monomer-removed BMI | — | IRGACURE-184 | (0.5) | CHN (90) | A | S | ◯ | S |
| 18 | citraconimide (10) | | | | | | | | |
| Example | High molecular weight | — | IRGACURE-184 | (0.5) | CHN (90) | A | S | ◯ | SS |
| 18A | BMI citraconimide | | | | | | | | |
| | polymer (10) | | | | | | | | |
| Example | Monomer-removed BAN | — | IRGACURE-184 | (0.5) | CHN (90) | A | S | ◯ | S |
| 19 | citraconimide (10) | | | | | | | | |
| Example | High molecular weight | — | IRGACURE-184 | (0.5) | CHN (90) | A | S | ◯ | SS |
| 19A | BAN citraconimide | | | | | | | | |
| | polymer (10) | | | | | | | | |
| Example | Monomer-removed BMI- | — | WPBG-300 | (0.5) | CHN (90) | S | S | ◯ | S |
| 20 | 2300 (10) | | | | | | | | |
| Example | High molecular weight | — | WPBG-300 | (0.5) | CHN (90) | S | S | ◯ | SS |
| 20A | BMI-2300 polymer (10) | | | | | | | | |
| Example | Monomer-removed MIR- | — | WPBG-300 | (0.5) | CHN (90) | S | S | ◯ | S |
| 21 | 3000-L (10) | | | | | | | | |
| Example | High molecular weight | — | WPBG-300 | (0.5) | CHN (90) | S | S | ◯ | SS |
| 21A | MIR-3000-L polymer (10) | | | | | | | | |
| Example | Monomer-removed BMI | — | WPBG-300 | (0.5) | CHN (90) | A | S | ◯ | S |
| 22 | citraconimide (10) | | | | | | | | |
| Example | High molecular weight | — | WPBG-300 | (0.5) | CHN (90) | A | S | ◯ | SS |
| 22A | BMI citraconimide | | | | | | | | |
| | polymer (10) | | | | | | | | |
| Example | Monomer-removed BAN | — | WPBG-300 | (0.5) | CHN (90) | A | S | ◯ | S |
| 23 | citraconimide (10) | | | | | | | | |
| Example | High molecular weight | — | WPBG-300 | (0.5) | CHN (90) | A | S | ◯ | SS |
| 23A | BAN citraconimide | | | | | | | | |
| | polymer (10) | | | | | | | | |

*The value shown in the parentheses represent parts by mass of each component.

### Example 24

A SiO₂ substrate with a film thickness of 300 nm was coated with the composition for film formation for lithography in Example 1, and baked at 240° C. for 60 seconds and further at 400° C. for 120 seconds to form an underlayer film with a film thickness of 70 nm. This underlayer film was coated with a resist solution for ArF and baked at 130° C. for 60 seconds to form a photoresist layer with a film thickness of 140 nm. The resist solution for ArF used was prepared by compounding 5 parts by mass of a compound of the following formula (4), 1 part by mass of triphenylsulfonium nonafluoromethanesulfonate, 2 parts by mass of tributylamine, and 92 parts by mass of PGMEA.

Note that the compound of the following formula (4) was prepared as follows. That is, 4.15 g of 2-methyl-2-methacryloyloxyadamantane, 3.00 g of methacryloyloxy-γ-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The product resin thus obtained was solidified and purified, and the resulting white powder was filtered and dried overnight at 40° C. under reduced pressure to obtain a compound represented by the following formula.

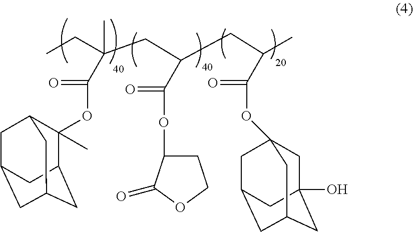

In the above formula (4), 40, 40, and 20 represent the ratio of each constituent unit and do not represent a block copolymer.

Subsequently, the photoresist layer was exposed using an electron beam lithography system (ELS—7500 manufactured by ELIONIX INC., 50 keV), baked (PEB) at 115° C. for 90 seconds, and developed for 60 seconds in a 2.38% by mass tetramethylammonium hydroxide (TMAH) aqueous solution to obtain a positive type resist pattern. The evaluation results are shown in Table 3.

### Example 25

A positive type resist pattern was obtained in the same way as Example 24 except that the composition for underlayer film formation for lithography in Example 2 was used instead of the composition for underlayer film formation for lithography in the above Example 1. The evaluation results are shown in Table 3.

### Comparative Example 5

The same operations as in Example 24 were carried out except that no underlayer film was formed so that a photoresist layer was formed directly on a SiO₂ substrate to obtain a positive type resist pattern. The evaluation results are shown in Table 3.

### [Evaluation]

Concerning each of Examples 24 to 25 and Comparative Example 5, the shapes of the obtained 55 nm L/S (1:1) and 80 nm L/S (1:1) resist patterns were observed under an electron microscope (S—4800) manufactured by Hitachi, Ltd. The shapes of the resist patterns after development were evaluated as goodness when having good rectangularity without pattern collapse, and as poorness if this was not the case. The smallest line width having good rectangularity without pattern collapse as a result of this observation was used as an index for resolution evaluation. The smallest electron beam energy quantity capable of lithographing good pattern shapes was used as an index for sensitivity evaluation.

TABLE 3

| | Composition for | | | Resist pattern |
|---|---|---|---|---|
| | film formation | Resolution | Sensitivity | shape after |
| | for lithography | (nm L/S) | (μC/cm²) | development |
| Example 24 | Composition | 60 | 16 | Goodness |
| | described in | | | |
| | Example 1 | | | |
| Example 25 | Composition | 60 | 15 | Goodness |
| | described in | | | |
| | Example 2 | | | |
| Comparative | None | 90 | 42 | Poorness |
| Example 5 | | | | |

As is evident from Table 3, it was confirmed that Examples 24 to 25, in which the compositions for film formation for lithography of the present embodiment comprising maleimide resins were used, are significantly superior in both resolution and sensitivity to Comparative Example 5. Also, the resist pattern shapes after development were confirmed to have good rectangularity without pattern collapse. Furthermore, the difference in the resist pattern shapes after development indicated that the underlayer films of Examples 24 to 25 obtained from the compositions for film formation for lithography of Examples 1 to 2 have good adhesiveness to a resist material.

### Examples 26 to 40

A clean silicon wafer was spin coated with each of these compositions for underlayer film formation for lithography in the above Examples 1A to 15A, and then baked with a hot plate at 150° C. to form a film with a thickness of 70 nm. When those films were observed under an optical microscope, no foreign matter was observed in any of them, confirming that the film formation is good.

### Comparative Examples 6 to 9

A clean silicon wafer was spin coated with each of these compositions for underlayer film formation for lithography in the above Comparative Examples 1 to 4, and then baked with a hot plate at 110° C. to form a film with a thickness of 70 nm. When those films were observed under an optical microscope, foreign matter was partially observed in all of them, confirming that the film formation is poor.

The present application is based on Japanese Patent Application No. 2018-218125 filed in the Japan Patent Office on Nov. 21, 2018, the contents of which are incorporated herein by reference.

### INDUSTRIAL APPLICABILITY

The film forming material for lithography of the present embodiment has good solvent solubility and is applicable to a wet process. Since the film forming material for lithography of the present embodiment is a resin having a rigid aromatic maleimide skeleton and further comprising components with a certain molecular weight or more, the production of sublimates or decomposition products is suppressed even with high temperature baking during thin film formation, and thus, the material has relatively high heat resistance, and excellent embedding properties to a substrate having difference in level and film flatness. Therefore, the composition for film formation for lithography comprising the film forming material for lithography can be utilized widely and effectively in various applications that require such performances. In particular, the present invention can be utilized particularly effectively in the field of underlayer films for lithography and underlayer films for multilayer resist.

1. A film forming material for lithography comprising a maleimide resin represented by the following formula (1A): 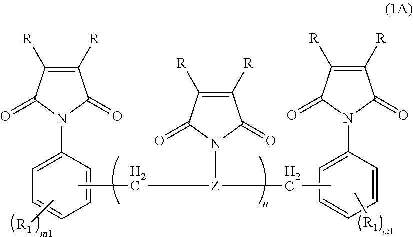
wherein
each R is independently any one group selected from the group consisting of a hydrogen atom and an alkyl group having 1 to 4 carbon atoms;
each Z is independently a trivalent or tetravalent hydrocarbon group having 1 to 100 carbon atoms and optionally containing a heteroatom;
each R₁ is independently a group having 0 to 10 carbon atoms and optionally containing a heteroatom;
each m1 is independently an integer of 0 to 4; and
n is an integer of 1 or more.

2. The film forming material for lithography according to claim 1, wherein n is an integer of 2 or more.

3. The film forming material for lithography according to claim 1, wherein the maleimide resin of formula (1A) is represented by the following formula (2A): 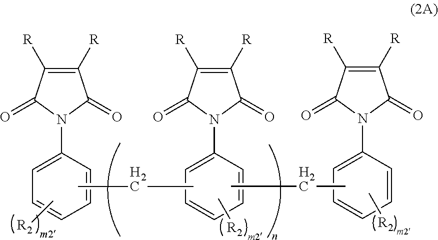
wherein R is as defined in formula (1A);
each R₂ is independently a group having 0 to 10 carbon atoms and optionally containing a heteroatom;
each m2 is independently an integer of 0 to 3;
each m2′ is independently an integer of 0 to 4; and
n is an integer of 1 or more,
or by the following formula (3A): 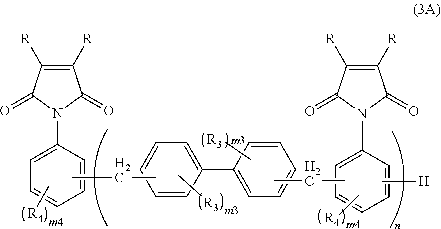
wherein R is as defined in formula (1A);
R₃ and R₄ are each independently a group having 0 to 10 carbon atoms and optionally containing a heteroatom;
each m3 is independently an integer of 0 to 4;
each m4 is independently an integer of 0 to 4; and
n is an integer of 2 or more.

4. The film forming material for lithography according to claim 1, wherein the heteroatom is selected from the group consisting of oxygen, fluorine, and silicon.

5. The film forming material for lithography according to claim 1, further comprising a crosslinking agent.

6. The film forming material for lithography according to claim 5, wherein the crosslinking agent is at least one selected from the group consisting of a phenol compound, an epoxy compound, a cyanate compound, an amino compound, a benzoxazine compound, a melamine compound, a guanamine compound, a glycoluril compound, a urea compound, an isocyanate compound, and an azide compound.

7. The film forming material for lithography according to claim 5, wherein the crosslinking agent has at least one allyl group.

8. The film forming material for lithography according to claim 1, further comprising a crosslinking promoting agent.

9. The film forming material for lithography according to claim 8, wherein the crosslinking promoting agent is at least one selected from the group consisting of an amine, an imidazole, an organic phosphine, and a Lewis acid.

10. The film forming material for lithography according to claim 8, wherein a content ratio of the crosslinking promoting agent is 0.1 to 5 parts by mass based on 100 parts by mass of a total mass of the maleimide resin.

11. The film forming material for lithography according to claim 1, further comprising a radical polymerization initiator.

12. The film forming material for lithography according to claim 11, wherein the radical polymerization initiator is at least one selected from the group consisting of a ketone-based photopolymerization initiator, an organic peroxide-based polymerization initiator, and an azo-based polymerization initiator.

13. The film forming material for lithography according to claim 11, wherein a content ratio of the radical polymerization initiator is 0.05 to 25 parts by mass based on 100 parts by mass of a total mass of the maleimide resin.

14. A composition for film formation for lithography comprising the film forming material for lithography according to claim 1 and a solvent.

15. The composition for film formation for lithography according to claim 14, further comprising a base generating agent.

16. The composition for film formation for lithography according to claim 14, wherein the film for lithography is an underlayer film for lithography.

17. An underlayer film for lithography formed by using the composition for film formation for lithography according to claim 16.

18. A method for forming a resist pattern, comprising the steps of:
forming an underlayer film on a substrate by using the composition for film formation for lithography according to claim 16;
forming at least one photoresist layer on the underlayer film; and
irradiating a predetermined region of the photoresist layer with radiation for development.

19. A method for forming a circuit pattern, comprising the steps of:
forming an underlayer film on a substrate by using the composition for film formation for lithography according to claim 16;
forming an intermediate layer film on the underlayer film by using a resist intermediate layer film material containing a silicon atom;
forming at least one photoresist layer on the intermediate layer film;
irradiating a predetermined region of the photoresist layer with radiation for development, thereby forming a resist pattern;
etching the intermediate layer film with the resist pattern as a mask;
etching the underlayer film with the obtained intermediate layer film pattern as an etching mask; and
etching the substrate with the obtained underlayer film pattern as an etching mask, thereby forming a pattern on the substrate.
